(19) United States
(12) Patent Application Publication
(10) Pub. No.: US 2024/0313018 A1
(43) Pub. Date: Sep. 19, 2024

(54) IMAGE SENSOR AND METHOD OF FABRICATING THE SAME

(71) Applicant: SAMSUNG ELECTRONICS CO., LTD., Suwon-si (KR)

(72) Inventors: Hye Yeon PARK, Suwon-si (KR); Yun Ki LEE, Suwon-si (KR)

(73) Assignee: SAMSUNG ELECTRONICS CO., LTD., Suwon-si (KR)

(21) Appl. No.: 18/535,561

(22) Filed: Dec. 11, 2023

(30) Foreign Application Priority Data
Mar. 15, 2023 (KR) 10-2023-0033743
Jun. 26, 2023 (KR) 10-2023-0081886

(51) Int. Cl. H01L 27/146

(52) U.S. Cl. CPC H01L 27/1463; H01L 27/14627; H01L 27/14636; H01L 27/14643; H01L 27/14685; H01L 27/14689

(57) ABSTRACT

An image sensor includes: a semiconductor substrate of a first conductivity type, the semiconductor substrate including: a first surface, a second surface opposite to the first surface, a pixel region, and a pixel isolation structure; and a photoelectric conversion region in the pixel region, the photoelectric conversion region having an impurity of a second conductivity type, wherein the pixel isolation structure is configured to enclose the photoelectric conversion region, and wherein the pixel isolation structure comprises: an air gap, a liner insulating pattern between the air gap and the semiconductor substrate, and a capping pattern adjacent to the second surface of the semiconductor substrate.

### CROSS-REFERENCE TO RELATED APPLICATIONS

This application is based on and claims priority under 35 U.S.C. § 119 to Korean Patent Application Nos. 10-2023-0033743, filed on Mar. 15, 2023, and 10-2023-0081886, filed on Jun. 26, 2023, respectively, in the Korean Intellectual Property Office, the entire contents of which are hereby incorporated by reference.

### BACKGROUND

### 1. Field

The disclosure relates to an image sensor and a method of fabricating the same, and in particular, to an image sensor with improved electrical and optical characteristics and a method of fabricating the same.

### 2. Description of Relate Art

An image sensor converts optical signals into electrical signals. With the development of the computer and communications industries, there is an increasing demand for high-performance image sensors in a variety of applications such as digital cameras, camcorders, personal communication systems, gaming machines, security cameras, micro-cameras for medical applications, or robots. The image sensors are generally classified into charge-coupled device (CCD) and complementary metal-oxide semiconductor (CMOS) image sensors.

The CMOS image sensor may be operated in a simplified manner. Since signal-processing circuits of the CMOS image sensor may be integrated on a single chip, it may possible to reduce a size of a product having the CMOS image sensor. In one embodiment, since the CMOS image sensor may be operated with a relatively low power consumption, it may be easily applied to an electronic device with a limited battery capacity. Furthermore, since the CMOS image sensor may be fabricated using the existing CMOS fabrication techniques, it may possible to reduce manufacturing cost of the CMOS image sensor. In one embodiment, due to increased resolutions of CMOS image sensors, the CMOS image sensors have been used more rapidly.

### SUMMARY

Provided is an image sensor with improved electrical and optical characteristics. Provided is a method of fabricating an image sensor with improved electrical and optical characteristics.

According to an aspect of the disclosure, an image sensor includes: a semiconductor substrate of a first conductivity type, the semiconductor substrate including: a first surface, a second surface opposite to the first surface, a pixel region, and a pixel isolation structure; and a photoelectric conversion region in the pixel region, the photoelectric conversion region having an impurity of a second conductivity type, wherein the pixel isolation structure is configured to enclose the photoelectric conversion region, and wherein the pixel isolation structure comprises: an air gap, a liner insulating pattern between the air gap and the semiconductor substrate, and a capping pattern adjacent to the second surface of the semiconductor substrate.

According to an aspect of the disclosure, an image sensor includes: a semiconductor substrate of a first conductivity type, the semiconductor substrate including: a first surface comprising a device isolation layer defining an active region, a second surface opposite to the first surface, a pixel region, and a pixel isolation structure defining the pixel region; and a photoelectric conversion region in the pixel region, the photoelectric conversion region having an impurity of a second conductivity type, wherein the pixel isolation structure comprises: an air gap, a liner insulating pattern between the air gap and the semiconductor substrate, and a gapfill insulating pattern adjacent to the first surface of the semiconductor substrate, and wherein the pixel isolation structure is provided to penetrate a portion of the device isolation layer and is extended from the first surface of the semiconductor substrate to the second surface of the semiconductor substrate.

According to an aspect of the disclosure, an image sensor includes: a semiconductor substrate comprising: a light-receiving region, a light-blocking region, a pad region, a first surface, a second surface opposite to the first surface; a pixel isolation structure in the light-receiving region and the light-blocking region of the semiconductor substrate, the pixel isolation structure and the light-blocking region defining a plurality of pixel regions: a transfer gate electrode on the first surface of the semiconductor substrate; a plurality of photoelectric conversion regions in the light-receiving region and the light-blocking region of the semiconductor substrate: a pixel circuit layer on the first surface of the semiconductor substrate; and an optically-transparent layer on the second surface of the semiconductor substrate, wherein the pixel isolation structure comprises a first pixel isolation structure on the light-receiving region and a second pixel isolation structure on the light-blocking region, wherein the first pixel isolation structure comprises an air gap, and wherein the second pixel isolation structure comprises a sacrificial pattern.

According to an aspect of the disclosure, a method of fabricating an image sensor, includes: providing a semiconductor substrate; removing a portion of the semiconductor substrate to form a pixel isolation trench: forming a preliminary pixel isolation structure in the pixel isolation trench: forming an internal space by removing a portion of the preliminary pixel isolation structure; and forming a capping layer on the semiconductor substrate, wherein the forming of the capping layer comprises forming an air gap by sealing the internal space.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an image sensor according to an embodiment of the disclosure:

FIGS. 2A and 2B are circuit diagrams illustrating a unit pixel of an image sensor according to an embodiment of the disclosure:

FIG. 3 is a plan view illustrating an image sensor according to an embodiment of the disclosure:

FIG. 4 is a sectional view taken along a line I-I′ of FIG. 3 to illustrate an image sensor according to an embodiment of the disclosure:

FIGS. 5A, 5B, and 5C are enlarged sectional views illustrating a portion (e.g., A of FIG. 4) of an image sensor according to an embodiment of the disclosure:

FIGS. 6 and 7 are sectional views taken along the line I-I′ of FIG. 3 to illustrate an image sensor according to an embodiment of the disclosure:

FIG. 8 is a plan view illustrating an image sensor according to an embodiment of the disclosure:

FIG. 9 is a sectional view taken along a line I-I′ of FIG. 8 to illustrate an image sensor according to an embodiment of the disclosure:

FIG. 10 is a plan view illustrating an image sensor according to an embodiment of the disclosure:

FIG. 11 is a sectional view taken along a line I-I′ of FIG. 10 to illustrate an image sensor according to an embodiment of the disclosure:

FIGS. 12 to 19 are sectional views taken along the line I-I′ of FIG. 3 to illustrate a method of fabricating an image sensor according to an embodiment of the disclosure;

FIG. 20 is a schematic plan view illustrating an image sensor including a semiconductor device according to an embodiment of the disclosure; and

FIGS. 21A and 21B are sectional views taken along a line I-I′ of FIG. 20 to illustrate an image sensor according to an embodiment of the disclosure.

### DETAILED DESCRIPTION

Example embodiments of the disclosures will now be described more fully with reference to the accompanying drawings, in which example embodiments are shown. Like reference numerals in the drawings denote like elements, and thus their description will be omitted.

The embodiments described herein are non-limiting example embodiments, and thus, the disclosure is not limited thereto and may be realized in various other forms.

Although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

When an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. In one embodiment, “at least one of A, B, and C” includes any of the following combinations: A, B, C, A and B, A and C, B and C, and A and B and C, and any variations thereof. Similarly, the term “set” means one or more. Accordingly, the set of items may be a single item or a collection of two or more items.

In the detailed description, components described with reference to the terms “part”, “unit”, “module”, “block”, “˜er or ˜or”, etc. and function blocks illustrated in drawings will be implemented with software, hardware, or a combination thereof. In one embodiment, the software may be a machine code, firmware, an embedded code, and application software. In one embodiment, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

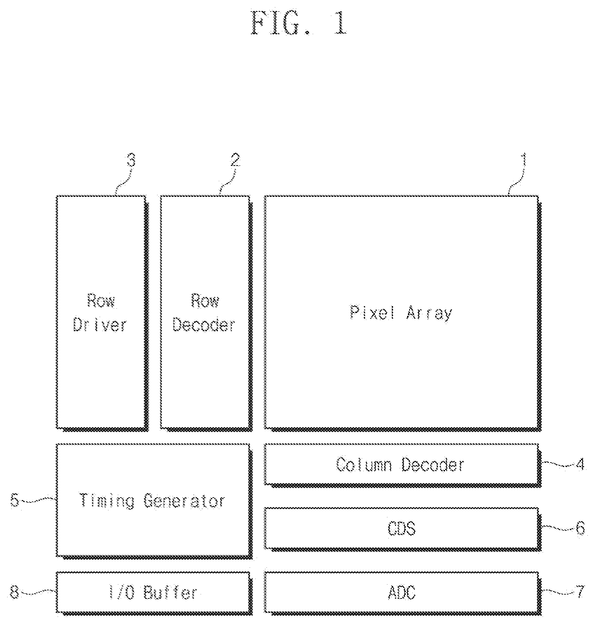

FIG. 1 is a block diagram illustrating an image sensor according to an embodiment of the disclosure.

In FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 may include a plurality of unit pixels that are arranged two-dimensionally to convert optical signals to electrical signals. The active pixel sensor array 1 may be driven by a plurality of driving signals, such as a pixel selection signal, a reset signal, and a charge transfer signal, which are transmitted from the row driver 3. In one embodiment, the converted electrical signals may be provided to the CDS 6.

The row driver 3 may be configured to provide the driving signals for driving the plurality of unit pixels to the active pixel sensor array 1, based on the result decoded by the row decoder 2. In the case where the unit pixels are arranged in a matrix shape (i.e., in rows and columns), the driving signals may be provided to respective rows.

The timing generator 5 may be configured to provide timing and control signals to the row decoder 2 and the column decoder 4.

The CDS 6 may be configured to receive the electric signals generated in the active pixel sensor array 1 and to perform a holding and sampling operation on the received electric signals. In one embodiment, the CDS 6 may perform a double sampling operation on a specific noise level and a signal level of the electric signal and may output a difference level corresponding to a difference between the noise and signal levels.

The ADC 7 may be configured to convert analog signals, which correspond to the level output from the CDS 6, into digital signals, and then to output the converted digital signals to the I/O buffer 8.

The I/O buffer 8 may be configured to latch the digital signal and to sequentially output the latched digital signals to an image signal processing unit, based on the result decoded by the column decoder 4.

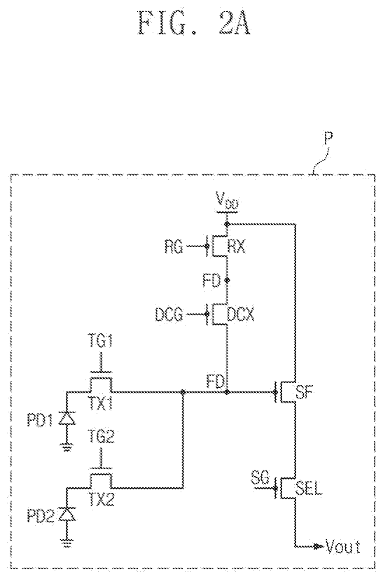

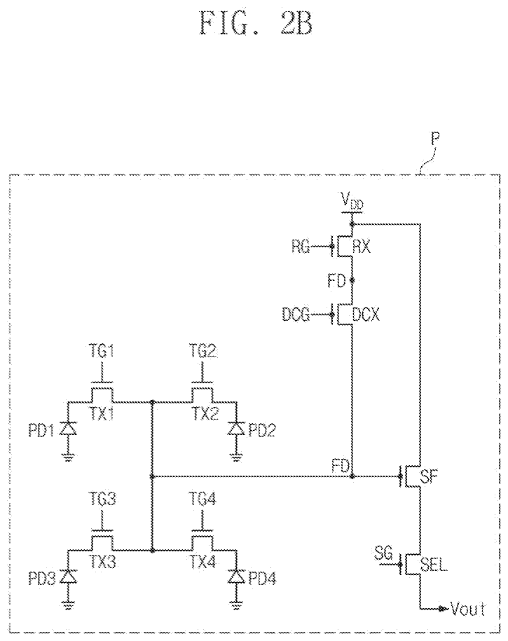

FIGS. 2A and 2B are circuit diagrams illustrating a unit pixel of an image sensor according to an embodiment of the disclosure.

In FIG. 2A, a unit pixel P may include a first photoelectric conversion device PD1, a second photoelectric conversion device PD2, a first transfer transistor TX1, a second transfer transistor TX2, and four pixel transistors. In one embodiment, each of the four pixel transistors may correspond to a reset transistor RX, a source follower transistor SF, a selection transistor SEL, and a dual conversion gain transistor DCX, but the disclosure is not limited to this example. In some embodiments, the pixel transistors in in each unit pixel P may be provided in various manners.

The first photoelectric conversion device PD1 and the second photoelectric conversion device PD2 may be configured to generate electric charges in response to an incident light. In this case, the generated electric charges may be accumulated in the first photoelectric conversion device PD1 and the second photoelectric conversion device PD2. In one embodiment, the first photoelectric conversion device PD1 and the second photoelectric conversion device PD2 may be photodiodes, phototransistors, photogates, or pinned photo diodes (PPDs).

The first transfer transistor TX1 and the second transfer transistor TX2 may be configured to transfer the electric charges, which are accumulated in the first photoelectric conversion device PD1 and the second photoelectric conversion device PD2, to a floating diffusion region FD. The first transfer transistor TX1 and the second transfer transistor TX2 may be controlled by signals that are applied to first and second transfer gate electrodes TG1 and TG2. The first transfer transistor TX1 and the second transfer transistor TX2 may share the floating diffusion region FD, but the disclosure is not limited to this example. That is, the first transfer transistor TX1 and the second transfer transistor TX2 may be connected to different ones of the floating diffusion regions FD, respectively.

The floating diffusion region FD may be configured to receive the electric charges, which are accumulated in the first or second photoelectric conversion device PD1 or PD2, and to cumulatively store the electric charges. The source follower transistor SF may be controlled by an amount of the photocharges stored in the floating diffusion region FD.

The reset transistor RX may periodically initialize electric charges, which are accumulated in the floating diffusion region FD, based on a reset signal applied to a reset gate electrode RG. In one embodiment, a drain terminal of the reset transistor RX may be connected to the dual conversion gain transistor DCX, and a source terminal may be connected to a pixel power voltage VDD. When the reset transistor RX and the dual conversion gain transistor DCX are turned on, the pixel power voltage VDD may be transmitted to the floating diffusion region FD. Accordingly, the electric charges accumulated in the floating diffusion region FD may be released, causing the floating diffusion region FD to be reset.

The dual conversion gain transistor DCX may be provided between and connected to the floating diffusion region FD and the reset transistor RX. The dual conversion gain transistor DCX may control a conversion gain by changing the capacitance of the floating diffusion region FD in response to a dual conversion gain control signal. That is, the dual conversion gain transistor DCX may be configured to achieve at least two different values of the conversion gain. Thus, the dual conversion gain transistor DCX may be turned on in a high brightness mode and may be turned off in a low brightness mode.

The source follower transistor SF may be a source follower buffer amplifier that is configured to produce a source-drain current in proportion to the amount of electric charges input from the floating diffusion region FD to a gate electrode of the source follower transistor SF. The source follower transistor SF may amplify a variation in electric potential of the floating diffusion region FD and may output the amplified signal to an output line Vout through the selection transistor SEL. The source follower transistor SF may be connected to the pixel power voltage VDD and the selection transistor SEL. That is, the source follower transistor SF may be placed between the pixel power voltage VDD and the selection transistor SEL.

The selection transistor SEL may be used to select a specific row of the unit pixels P to be read out during a read operation. When the selection transistor SEL is turned on by a selection signal applied to a selection gate electrode SG, an electrical signal, which is output to a drain electrode of the source follower transistor SF, may be output to the output line Vout.

In FIG. 2B, the unit pixel P may include first to fourth photoelectric conversion devices PD1, PD2, PD3, and PD4, first to fourth transfer transistors TX1, TX2, TX3, and TX4, and four pixel transistors.

The first to fourth transfer transistors TX1, TX2, TX3, and TX4 may be configured to share the floating diffusion region FD. The first to fourth transfer transistors TX1, TX2, TX3, and TX4 may be controlled by signals applied to first to fourth transfer gate electrodes TG1, TG2, TG3, and TG4.

The four pixel transistors may correspond to the reset transistor RX, the source follower transistor SF, the selection transistor SEL, and the dual conversion gain transistor DCX described with reference to FIG. 2A.

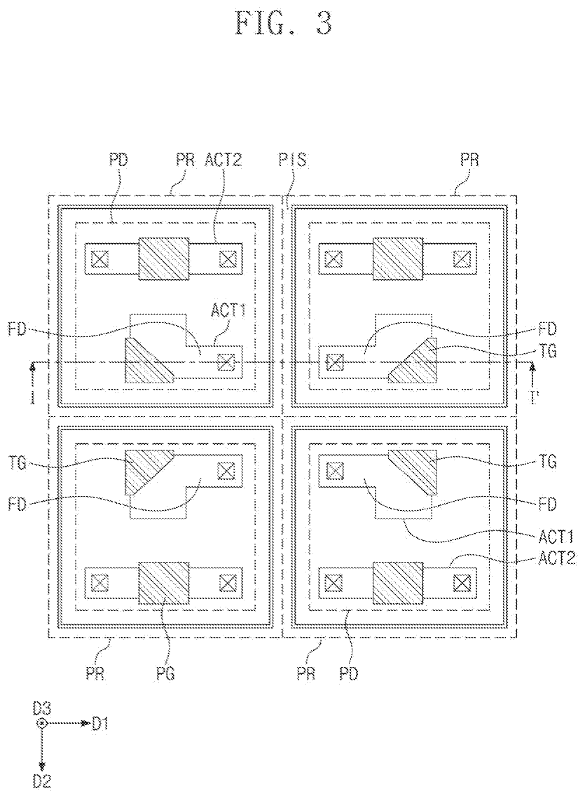

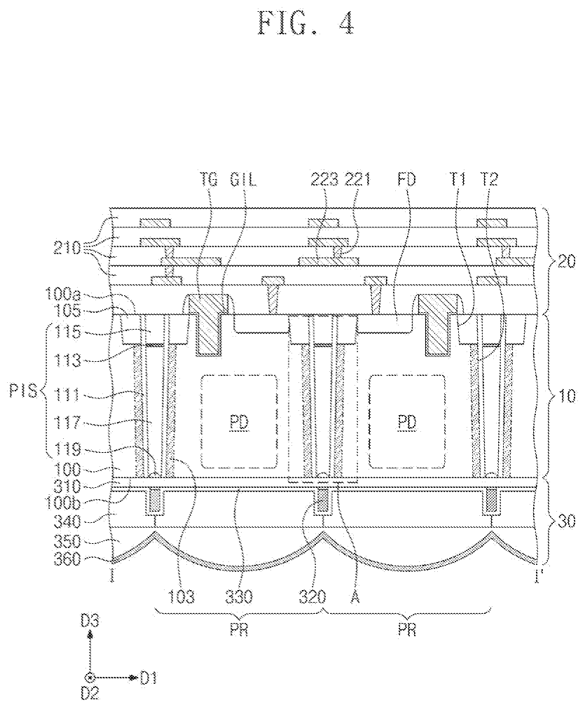

FIG. 3 is a plan view illustrating an image sensor according to an embodiment of the disclosure. FIG. 4 is a sectional view taken along a line I-I′ of FIG. 3 to illustrate an image sensor according to an embodiment of the disclosure.

In FIGS. 3 and 4, the image sensor may include a photoelectric conversion layer 10, a pixel circuit layer 20, and an optically-transparent layer 30, when viewed in a vertical section.

The photoelectric conversion layer 10 may be disposed between the pixel circuit layer 20 and the optically-transparent layer 30, when viewed in a vertical section. The photoelectric conversion layer 10 may be configured to convert light, which is incident from the outside, to electrical signals. The photoelectric conversion layer 10 may include a semiconductor substrate 100 and a pixel isolation structure PIS, a barrier region 103, and photoelectric conversion regions PD, which are provided in the semiconductor substrate 100.

In one embodiment, the semiconductor substrate 100 may have a first surface 100a and a second surface 100b, which are opposite to each other. The semiconductor substrate 100 may be a substrate including a bulk silicon substrate and an epitaxial layer, which are sequentially stacked and are of a first conductivity type (e.g., p-type), and in the case where the bulk silicon substrate is removed during a fabrication process of an image sensor, the semiconductor substrate 100 may be composed of only the p-type epitaxial layer. In an embodiment, the semiconductor substrate 100 may be a bulk semiconductor substrate including a well of the first conductivity type.

In each of pixel regions PR, a device isolation layer 105 may be disposed adjacent to the first surface 100a of the semiconductor substrate 100. The device isolation layer 105 may be provided in a device isolation trench T1, which is formed by recessing the first surface 100a of the semiconductor substrate 100. The device isolation layer 105 may be formed of or include an insulating material. The device isolation layer 105 may define an active portion in the semiconductor substrate 100 and near the first surface 100a. In one embodiment, the device isolation layer 105 may define first and second active portions ACT1 and ACT2 in the semiconductor substrate 100. In each of the pixel regions PR, the first active portion ACT1 and the second active portion ACT2 may be spaced apart from each other and may have different sizes from each other.

The pixel isolation structure PIS may be provided in a pixel isolation trench T2, which is formed by recessing the first surface 100a of the semiconductor substrate 100. The pixel isolation structure PIS may define a plurality of the pixel regions PR. The pixel isolation structure PIS may be provided to penetrate the semiconductor substrate 100 from the first surface 100a to the second surface 100b. The pixel isolation structure PIS may penetrate a portion of the device isolation layer 105.

The pixel isolation structure PIS may include portions, which are extended in a first direction D1 to be parallel to each other, and portions, which are extended in a second direction D2 to be parallel to each other. When viewed in a plan view, the pixel isolation structure PIS may be provided to enclose each of the pixel regions PR or each of the photoelectric conversion regions PD.

The pixel isolation structure PIS may have an upper width at a level of the first surface 100a of the semiconductor substrate 100 and may have a lower width at a level of the second surface 100b of the semiconductor substrate 100. In one embodiment, the lower width may be smaller than the upper width. In one embodiment, a width of the pixel isolation structure PIS may gradually decrease as a distance from the first surface 100a of the semiconductor substrate 100 increases in a direction toward the second surface 100b. The pixel isolation structure PIS may have a length in a third direction D3. A length of the pixel isolation structure PIS may be substantially equal to a vertical thickness of the semiconductor substrate 100.

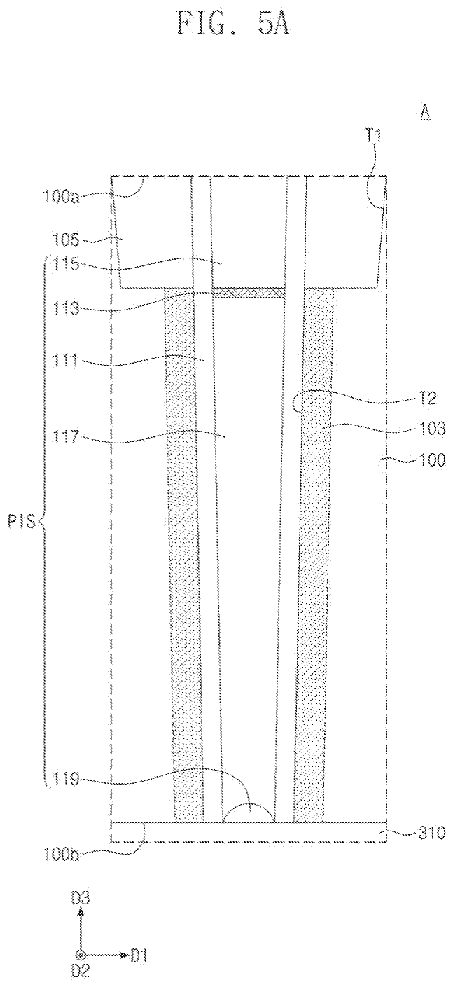

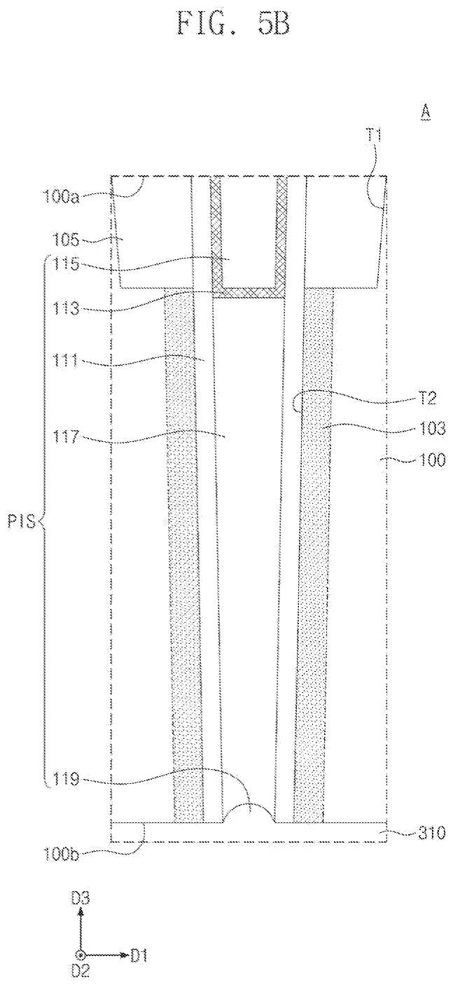

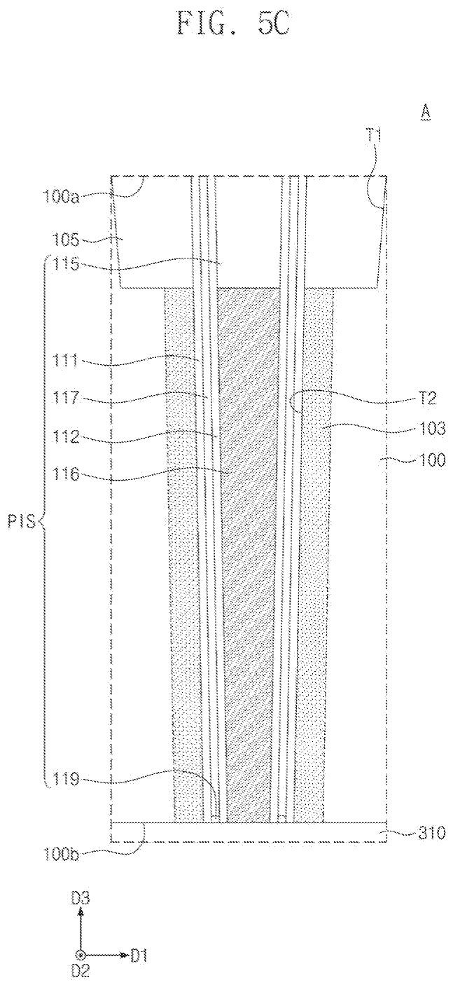

The pixel isolation structure PIS may include a liner insulating pattern 111, an etch stop layer 113, a gapfill insulating pattern 115, an air gap 117, and a capping pattern 119. The pixel isolation structure PIS will be described in more detail with reference to FIGS. 5A to 5C.

The barrier region 103 may be provided in a portion of the semiconductor substrate 100, which is adjacent to a side surface of the pixel isolation structure PIS. The barrier region 103 may contain impurities, which are of the same conductivity type (e.g., the first conductivity type or the p-type) as the semiconductor substrate 100. The barrier region 103 may be in contact with a side surface of the liner insulating pattern 111 of the pixel isolation structure PIS. A surface defect of the pixel isolation trench T2 created during a process of forming the pixel isolation trench T2 may generate electron-hole pairs (EHP) causing a dark current, but the dark current may be reduced by the barrier region 103 according to an embodiment of the disclosure.

The photoelectric conversion regions PD may be provided in the pixel regions PR of the semiconductor substrate 100, respectively. The photoelectric conversion regions PD may generate photocharges in proportion to an intensity of an incident light. The photoelectric conversion regions PD may be formed by injecting impurities, which are of a second conductivity type different from a first conductivity type of the semiconductor substrate 100, into the semiconductor substrate 100. The photoelectric conversion region PD of the second conductivity type and the semiconductor substrate 100 of the first conductivity type may form a pn junction serving as a photodiode. In an embodiment, each of the photoelectric conversion regions PD may be provided to have a difference in doping concentration between portions adjacent to the first surface 100a and the second surface 100b, thereby having a non-vanishing gradient in potential between the first surface 100a and the second surface 100b of the semiconductor substrate 100. In one embodiment, the photoelectric conversion regions PD may include a plurality of impurity regions which are vertically stacked.

The pixel circuit layer 20 may be disposed on the first surface 100a of the semiconductor substrate 100. The pixel circuit layer 20 may include pixel circuits (e.g., MOS transistors), which are electrically connected to the photoelectric conversion regions PD. In one embodiment, the pixel circuit layer 20 may include the reset transistor RX, the selection transistor SEL, the dual conversion gain transistor DCX, and the source follower transistor SF, which are the pixel transistors described with reference to FIG. 2A.

In each of the pixel regions PR, a transfer gate electrode TG may be disposed on the first active portion ACT1 of the semiconductor substrate 100. The transfer gate electrode TG may be placed on the first surface 100a of the semiconductor substrate 100. The transfer gate electrode TG may be provided to penetrate a portion of the semiconductor substrate 100. In other words, the transfer gate electrode TG may have a shape of letter ‘T’, when viewed in a vertical section. A gate insulating layer GIL may be interposed between the transfer gate electrode TG and the semiconductor substrate 100.

The floating diffusion region FD may be provided in a portion of the first active portion ACT1 located at a side of the transfer gate electrode TG. The floating diffusion region FD may be formed by injecting impurities, which have a conductivity type different from the semiconductor substrate 100, into the semiconductor substrate 100. In one embodiment, the floating diffusion region FD may be an impurity region of the second conductivity type.

In each of the pixel regions PR, at least one pixel transistor may be provided on the second active portion ACT2. The pixel transistor, which is provided in each pixel region PR, may be one of the reset transistor RX, the source follower transistor SF, the dual conversion gain transistor DCX, and the selection transistor SEL described with reference to FIGS. 2A and 2B. The pixel transistor may include a pixel gate electrode PG, which is provided to cross the second active portion ACT2, and source/drain regions, which are provided in portions of the second active portion ACT2 located at both sides of the pixel gate electrode PG. The pixel gate electrode PG may have a bottom surface that is parallel to a top surface of the second active portion ACT2. The pixel gate electrode PG may be formed of or include at least one of, for example, doped polysilicon, metallic materials, conductive metal nitrides, conductive metal silicide materials, conductive metal oxide materials, or combinations thereof.

An interlayer insulating layers 210 may be placed on the first surface 100a of the semiconductor substrate 100 and may be composed of a plurality of layers. The interlayer insulating layers 210 may cover the transfer gate electrode TG and an interconnection structure, which is connected to the pixel circuits. The interconnection structure may include metal lines 223 and contact plugs 221 connecting the metal lines 223 to each other.

The optically-transparent layer 30 may be disposed on the second surface 100b of the semiconductor substrate 100. The optically-transparent layer 30 may include a planarization insulating layer 310, a lattice structure 320, a protection layer 330, color filters 340, micro lenses 350, and a passivation layer 360. The optically-transparent layer 30 may be configured to perform an operation of focusing and filtering light, which is incident from the outside, and to provide the light to the photoelectric conversion layer 10.

In one embodiment, the planarization insulating layer 310 may cover the second surface 100b of the semiconductor substrate 100. The planarization insulating layer 310 may be formed of a transparent insulating material and may include a plurality of layers. The planarization insulating layer 310 may be formed of an insulating material whose refractive index is different from the semiconductor substrate 100. The planarization insulating layer 310 may include at least one of metal oxide and/or silicon oxide. In one embodiment, the planarization insulating layer 310 may be formed of or include at least one of Al₂O₃, CeF₃, HfO2, ITO, MgO, Ta₂O₅, TiO₂, ZrO₂, Si, Ge, ZnSe, ZnS, or PbF₂. In one embodiment, the planarization insulating layer 310 may be formed of an organic material having a high refractive index and may include siloxane resin, Benzocyclobutene (BCB), polyimide-based materials, acryl-based materials, parylene C, poly(methyl methacrylate) (PMMA), or polyethylene terephthalate (PET). In one embodiment, the planarization insulating layer 310 may be formed of or include at least one of strontium titanate (SrTiO₃), polycarbonate, glass, bromine, sapphire, cubic zirconia, potassium niobate (KNbO₃), moissanite (SiC), gallium (III) phosphide (GaP), or gallium (III) arsenide (GaAs).

The lattice structure 320 may be disposed on the planarization insulating layer 310. When viewed in a plan view, the lattice structure 320 may have a lattice shape, similar to the pixel isolation structure PIS. When viewed in a plan view, the lattice structure 320 may be overlapped with the pixel isolation structure PIS. That is, the lattice structure 320 may include portions, which are extended in the first direction D1, and portions, which are extended in the second direction D2. A width of the lattice structure 320 may be substantially equal to or smaller than the smallest width of the pixel isolation structure PIS.

The lattice structure 320 may include a light-blocking pattern and/or a low-refractive pattern. The light-blocking pattern may be formed of or include at least one of metallic materials (e.g., titanium, tantalum, or tungsten). The low-refractive pattern may be formed of or include a material whose refractive index is lower than the light-blocking pattern. The low-refractive pattern may be formed of an organic material and may have a refractive index of about 1.1 to 1.3. In one embodiment, the lattice structure 320 may be a polymer layer including silica nano-particles.

The protection layer 330 may be provided to cover the planarization insulating layer 310 and the lattice structure 320. The protection layer 330 may have a substantially uniform thickness. The protection layer 330 may be a single- or multi-layered structure including at least one of an aluminum oxide layer and a silicon carbon oxide layer.

The color filters 340 may be formed on the protection layer 330 to correspond to the pixel regions PR, respectively. The color filters 340 may be provided to fill empty regions defined by the lattice structure 320. The color filters 340 may include red, green, or blue color filters or magenta, cyan, or yellow color filters, which are determined based on positions of the unit pixels.

The micro lenses 350 may be disposed on the color filters 340. The micro lenses 350 may have a convex shape and may have a specific curvature radius. The micro lenses 350 may be formed of or include at least one of optically-transparent resins.

The passivation layer 360 may be placed on the micro lenses 350 to conformally cover the micro lenses 350. The passivation layer 360 may be formed of or include at least one of inorganic oxide materials.

FIGS. 5A, 5B, and 5C are enlarged sectional views illustrating a portion (e.g., A of FIG. 4) of an image sensor according to an embodiment of the disclosure.

In FIG. 5A, the pixel isolation structure PIS may be provided in the pixel isolation trench T2 formed in the semiconductor substrate 100. The pixel isolation structure PIS may include the liner insulating pattern 111, the etch stop layer 113, the gapfill insulating pattern 115, the air gap 117, and the capping pattern 119. The pixel isolation structure PIS may have an aspect ratio of about 10:1 to 15:1.

The liner insulating pattern 111 may be placed in the pixel isolation trench T2 to cover the inner side surfaces of the pixel isolation trench T2. The liner insulating pattern 111 may be in direct contact with the semiconductor substrate 100. Since the liner insulating pattern 111 includes a material having a lower refractive index than the semiconductor substrate 100, a refractive index of the liner insulating pattern 111 may be lower than the refractive index of the semiconductor substrate 100.

In an embodiment, the liner insulating pattern 111 may include at least one of silicon-based insulating materials (e.g., silicon nitride, silicon oxide, and/or silicon oxynitride), high-k dielectric materials (e.g., hafnium oxide and/or aluminum oxide), and/or metal oxide materials and may be formed of or include, for example, aluminum oxide.

The liner insulating patterns 111 may contain impurities of a first conductivity type. In one embodiment, the impurities of the first conductivity type may include at least one of boron (B), phosphorus P, arsenic (As), gallium (Ga), indium (In), antimony (Sb), and aluminum (Al).

The gapfill insulating pattern 115 may be provided in an upper portion of the pixel isolation structure PIS and may be in contact with the liner insulating pattern 111. The gapfill insulating pattern 115 may be adjacent to the first surface 100a of the semiconductor substrate 100. A top surface of the gapfill insulating pattern 115 may be coplanar with the first surface 100a of the semiconductor substrate 100. The top and bottom surfaces of the gapfill insulating pattern 115 may be positioned at substantially the same levels as the top and bottom surfaces of the device isolation layer 105. In one embodiment, the gapfill insulating pattern 115 may be formed of or include at least one of silicon oxide, silicon nitride, or silicon oxynitride.

The etch stop layer 113 may be placed on the bottom surface of the gapfill insulating pattern 115 and may be in contact with the gapfill insulating pattern 115. The etch stop layer 113 may be closer to the first surface 100a of the semiconductor substrate 100 than to the second surface 100b. The etch stop layer 113 may have a substantially constant thickness and may cover the bottom surface of the gapfill insulating pattern 115. The etch stop layer 113 may include a material having an etch selectivity in an etching process. In one embodiment, the etch stop layer 113 may be formed of or include at least one of metal oxide materials, metal oxynitride materials, metal silicon oxide materials, and/or metal silicon oxynitride materials.

The capping pattern 119 may be provided in a lower portion of the pixel isolation structure PIS and may be in contact with the liner insulating pattern 111. The capping pattern 119 may be adjacent to the second surface 100b of the semiconductor substrate 100. A bottom surface of the capping pattern 119 may be located at substantially the same level as the second surface 100b of the semiconductor substrate 100. A top surface of the capping pattern 119 may have a convex shape in the third direction D3. In one embodiment, the capping pattern 119 may have a convex shape toward the first surface 100a of the semiconductor substrate 100 and may be spaced apart from the etch stop layer 113 and the gapfill insulating pattern 115. The capping pattern 119 may be in direct contact with the planarization insulating layer 310, which is provided on the second surface 100b of the semiconductor substrate 100.

The air gap 117 may be placed in the pixel isolation structure PIS. The liner insulating pattern 111 may be placed between the air gap 117 and the semiconductor substrate 100. The air gap 117 may be placed between the gapfill insulating pattern 115 and the capping pattern 119. That is, the air gap 117 may be enclosed by the liner insulating pattern 111, the gapfill insulating pattern 115, and the capping pattern 119. Thus, the air gap 117 may be spaced apart from the semiconductor substrate 100. In one embodiment, the air gap 117 may include the air and may have an air-containing porous structure. Thus, a refractive index of the air gap 117 may be lower than the refractive index of the liner insulating pattern 111.

In FIG. 5B, the etch stop layer 113 may be provided on bottom and side surfaces of the gapfill insulating pattern 115 and may be in direct contact with the gapfill insulating pattern 115. In one embodiment, the etch stop layer 113 may be extended from a region under the gapfill insulating pattern 115 to a region between the gapfill insulating pattern 115 and the liner insulating patterns 111.

The capping pattern 119 and the planarization insulating layer 310 may be provided in the form of a single object. The capping pattern 119 and the planarization insulating layer 310 may be formed of or include the same material, and there may be no observable interface between the capping pattern 119 and the planarization insulating layer 310. In other words, a length or a width of an interface between the capping pattern 119 and the planarization insulating layer 310 is zero, near zero, or not substantial. That is, the capping pattern 119 and the planarization insulating layer 310 may be a single element that is formed simultaneously using the single process.

In FIG. 5C, the pixel isolation structure PIS may further include an inner liner insulating pattern 112 and a sacrificial pattern 116, but the etch stop layer 113 of FIGS. 5A and 5B may be omitted from the pixel isolation structure PIS. The inner liner insulating pattern 112 and the sacrificial pattern 116 may be provided as inner elements of the pixel isolation structure PIS.

The inner liner insulating pattern 112 may be spaced further apart from the semiconductor substrate 100 than the air gap 117. That is, the air gap 117 may be placed between the inner liner insulating pattern 112 and the liner insulating pattern 111. A volume of the air gap 117 may be smaller than that in FIGS. 5A and 5B. The capping pattern 119 may be placed between the liner insulating pattern 111 and the inner liner insulating pattern 112. The inner liner insulating pattern 112 may be formed of or include substantially the same material as the liner insulating pattern 111. In one embodiment, the inner liner insulating pattern 112 may be formed of or include at least one of silicon-based insulating materials, high-k dielectric materials, and/or metal oxide materials and may contain impurities of the first conductivity type.

The sacrificial pattern 116 may be farther from the semiconductor substrate 100 than the inner liner insulating pattern 112. The liner insulating pattern 111, the air gap 117, the inner liner insulating pattern 112, and the sacrificial pattern 116 may be sequentially placed on a side surface of the semiconductor substrate 100. That is, the sacrificial pattern 116 may be placed at the center of the pixel isolation structure PIS. A top surface of the sacrificial pattern 116 may be located at substantially the same level as the bottom surface of the gapfill insulating pattern 115. A bottom surface of the sacrificial pattern 116 may be located at substantially the same level as the second surface 100b of the semiconductor substrate 100. In one embodiment, the sacrificial pattern 116 may include a doped poly-silicon layer and/or an undoped poly-silicon layer. In the case where the sacrificial pattern 116 includes a doped poly-silicon layer, the sacrificial pattern 116 may contain impurities of the first conductivity type.

Referring back to FIGS. 5A to 5C, the liner insulating pattern 111 and the air gap 117 may be sequentially placed on the side surface of the semiconductor substrate 100 exposed to the pixel isolation trench T2. The liner insulating pattern 111 may be located between the air gap 117 and the semiconductor substrate 100.

A refractive index of the liner insulating pattern 111 may be lower than a refractive index of the semiconductor substrate 100. A refractive index of the air gap 117 may be lower than the refractive index of the liner insulating pattern 111. Thus, incident light directed to the pixel isolation structure PIS may be reflected at an interface between the semiconductor substrate 100 and the liner insulating patterns 111 and an interface between the liner insulating patterns 111 and the air gap 117. In other words, the air gap 117 of the pixel isolation structure PIS may reflect the incident light such that the incident light is prevented from being absorbed by the pixel isolation structure PIS. Thus, the quantum efficiency (QE) of the image sensor may be increased, and as a result, the electrical or optical characteristics of the image sensor may be improved.

Hereinafter, other examples of the image sensor will be described below. However, for concise description, a previously described element may be identified by the same reference number without repeating an overlapping description thereof.

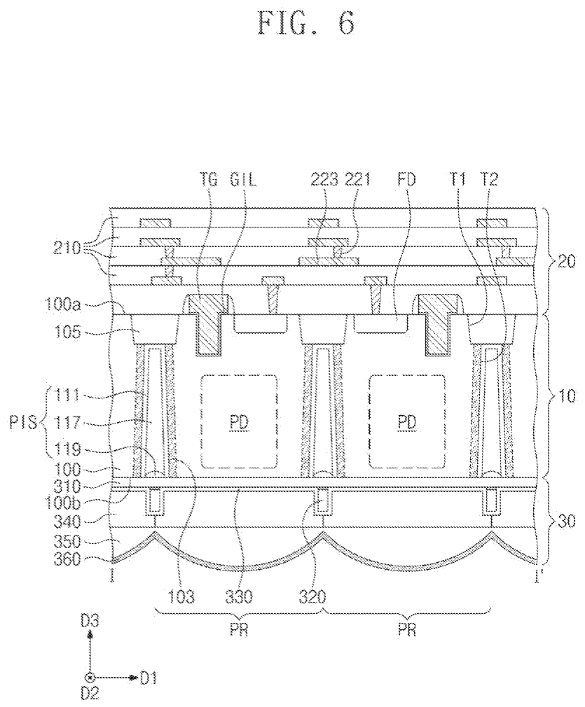

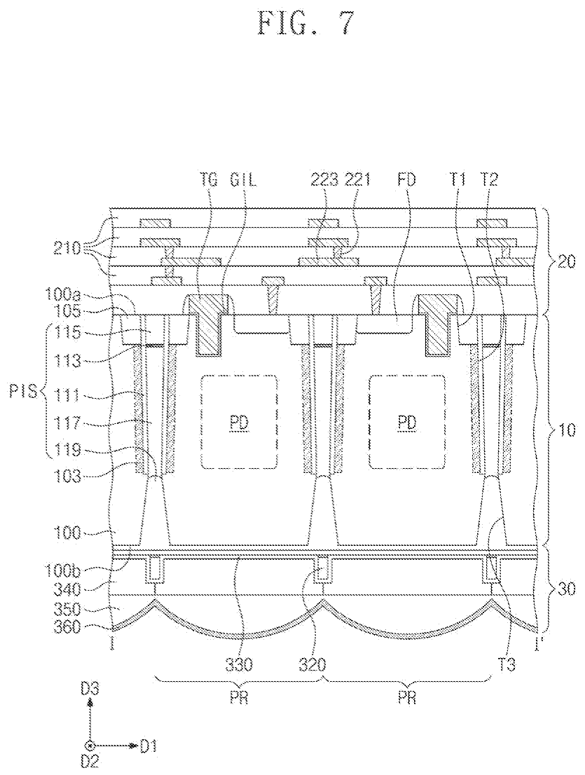

FIGS. 6 and 7 are sectional views taken along the line I-I′ of FIG. 3 to illustrate an image sensor according to an embodiment of the disclosure.

In FIG. 6, the pixel isolation structure PIS may have an upper width at a level of the first surface 100a of the semiconductor substrate 100. The pixel isolation structure PIS may have a lower width at a level of the second surface 100b of the semiconductor substrate 100. In one embodiment, the upper width may be smaller than the lower width. That is, a width of the pixel isolation structure PIS may gradually increase as a distance from the first surface 100a of the semiconductor substrate 100 increases in a direction toward the second surface 100b.

The liner insulating pattern 111 may include a horizontal portion and a vertical portion. The horizontal portion may be adjacent to the first surface 100a of the semiconductor substrate 100 and may be in contact with the device isolation layer 105. That is, the pixel isolation structure PIS may not penetrate a portion of the device isolation layer 105. The vertical portion may be extended from the horizontal portion. The vertical portion may have a shape extended in the third direction D3. That is, the liner insulating pattern 111 may have a shape of letter ‘U’, and the air gap 117 may be placed in the liner insulating pattern 111.

In FIG. 7, the pixel isolation structure PIS may have an upper width at a level of the first surface 100a of the semiconductor substrate 100. The pixel isolation structure PIS may have a lower width at a level of the second surface 100b of the semiconductor substrate 100. The pixel isolation structure PIS may have an intermediate width at an intermediate level of the semiconductor substrate 100. The upper width and the lower width may be substantially equal to each other. Each of the upper and lower widths may be larger than the intermediate width. A width of the pixel isolation structure PIS may decrease and then increase as a distance from the first surface 100a of the semiconductor substrate 100 increases in a direction toward the second surface 100b. That is, the width of the pixel isolation structure PIS may have the largest value at the levels of the first surface 100a and the second surface 100b of the semiconductor substrate 100 and may have the smallest value at the intermediate level of the semiconductor substrate 100.

A trench T3 may be provided to have a shape that is recessed from the second surface 100b of the semiconductor substrate 100. The capping pattern 119 may be placed in the trench T3. The capping pattern 119 may be provided to fill the trench T3 and have a convex shape toward the first surface 100a of the semiconductor substrate 100. In this case, the capping pattern 119 may be formed of at least one high-k dielectric material having a higher dielectric constant than a silicon oxide layer. In one embodiment, the capping pattern 119 may be formed of a metal oxide material or a metal fluoride material containing at least one metallic element that is selected from the group consisting of hafnium (Hf), zirconium (Zr), aluminum (Al), tantalum (Ta), titanium (Ti), yttrium (Y) and lanthanum (La).

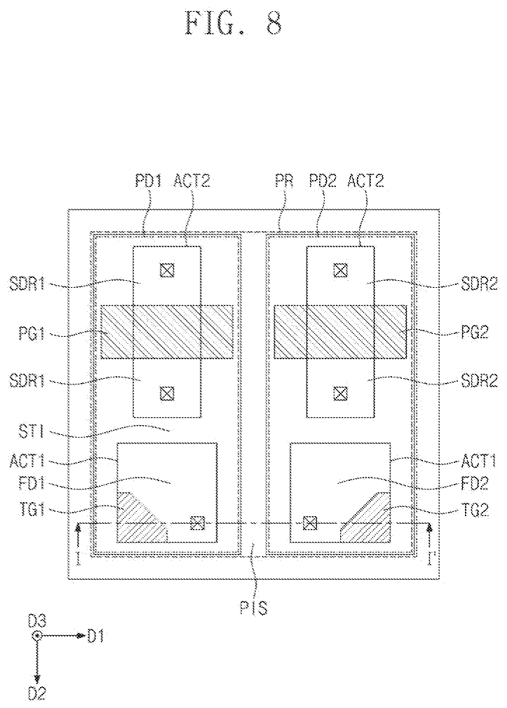

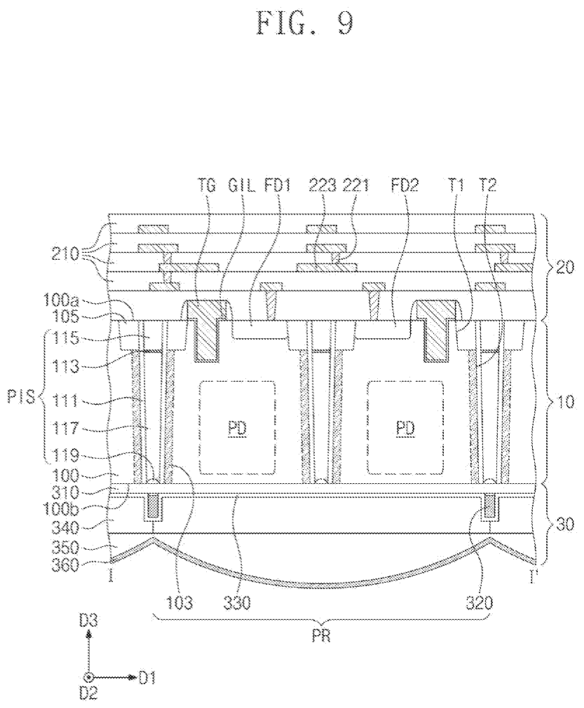

FIG. 8 is a plan view illustrating an image sensor according to an embodiment of the disclosure. FIG. 9 is a sectional view taken along a line I-I′ of FIG. 8 to illustrate an image sensor according to an embodiment of the disclosure.

In FIGS. 8 and 9, the first and second photoelectric conversion regions PD1 and PD2 may be provided in the pixel region PR of the semiconductor substrate 100. The first and second photoelectric conversion regions PD1 and PD2 may be configured to convert light, which is incident from the outside, to electrical signals.

The first and second photoelectric conversion regions PD1 and PD2 may be impurity regions, which are doped with impurities of a conductivity type (i.e., the second conductivity type) different from the first conductivity type of the semiconductor substrate 100. The semiconductor substrate 100 of the first conductivity type and the first and second photoelectric conversion regions PD1 and PD2 may constitute photodiodes. That is, a junction serving as a photodiode may be formed between the semiconductor substrate 100 of the first conductivity type and the first or second photoelectric conversion regions PD1 and PD2. In the case where light is incident into the first and second photoelectric conversion regions PD1 and PD2 constituting the photodiode, photocharges may be generated and accumulated in proportion to an intensity of the incident light.

In one pixel region PR, the electrical signals, which are outputted from the first and second photoelectric conversion regions PD1 and PD2, may have a phase difference. The image sensor may be configured to measure a distance to a target object from a difference in phase between the electrical signals, which are output from the paired photoelectric conversion regions (i.e., the first and second photoelectric conversion regions PD1 and PD2), to examine whether the target object is in focus or the degree to which it is out of focus, and to automatically correct the focus of the image sensor based the examined result.

The first and second photoelectric conversion regions PD1 and PD2 may have the same width in the first direction D1 and may have the same length in the second direction D2. A length of each of the first and second photoelectric conversion regions PD1 and PD2 may be larger than a width of each of the first and second photoelectric conversion regions PD1 and PD2. In one embodiment, in the first and second photoelectric conversion regions PD1 and PD2, the length may be about 2 times the width.

The pixel isolation structure PIS defining the pixel region PR may be provided in the semiconductor substrate 100. The pixel isolation structure PIS may include the liner insulating pattern 111, the etch stop layer 113, the gapfill insulating pattern 115, the air gap 117, and the capping pattern 119. In one embodiment, the pixel isolation structure may further include the inner liner insulating pattern 112 and the sacrificial pattern 116. That is, the pixel isolation structure PIS may be provided to have substantially the same features as that of FIGS. 5A to 5C.

When viewed in a plan view, the pixel isolation structure PIS may be provided to enclose or cross the pixel region PR. In one embodiment, the pixel isolation structure PIS may include portions, which are extended in a first direction D1 to be parallel to each other, and portions, which are extended in a second direction D2 to be parallel to each other. In one embodiment, the pixel isolation structure PIS may include a portion passing through the center of the pixel region PR in the second direction D2. Accordingly, the first and second photoelectric conversion regions PD1 and PD2 may be spaced apart from each other, with the pixel isolation structure PIS interposed therebetween, in the first direction D1.

Since the pixel isolation structure PIS includes the air gap 117 having a refractive index lower than the liner insulating pattern 111, the pixel isolation structure PIS may physically reflect the incident light, between the first and second photoelectric conversion regions PD1 and PD2. That is, it may be possible to prevent the incident light from being absorbed by the pixel isolation structure PIS between the first and second photoelectric conversion regions PD1 and PD2 and thereby to increase the quantum efficiency of the image sensor.

The lattice structure 320 may be disposed on the planarization insulating layer 310 of the optically-transparent layer 30. The lattice structure 320 may have a lattice shape that is similar to the pixel isolation structure PIS. When viewed in a plan view, the lattice structure 320 may be overlapped with the pixel isolation structure PIS. However, the lattice structure 320 may not be disposed between the first and second photoelectric conversion regions PD1 and PD2.

The color filters 340 may be disposed on the protection layer 330. Each of the color filters 340 may be formed to correspond to the pixel region PR. The color filters 340 may fill empty regions defined by the lattice structure 320. That is, each of the color filters 340 may be provided to correspond to the first and second photoelectric conversion regions PD1 and PD2 of a corresponding one of the pixel regions PR.

The micro lenses 350 may be placed on the color filters 340. The micro lenses 350 may be disposed on the color filters 340 corresponding to the pixel regions PR, respectively. That is, the micro lenses 350 may be disposed in common on the first and second photoelectric conversion regions PD1 and PD2.

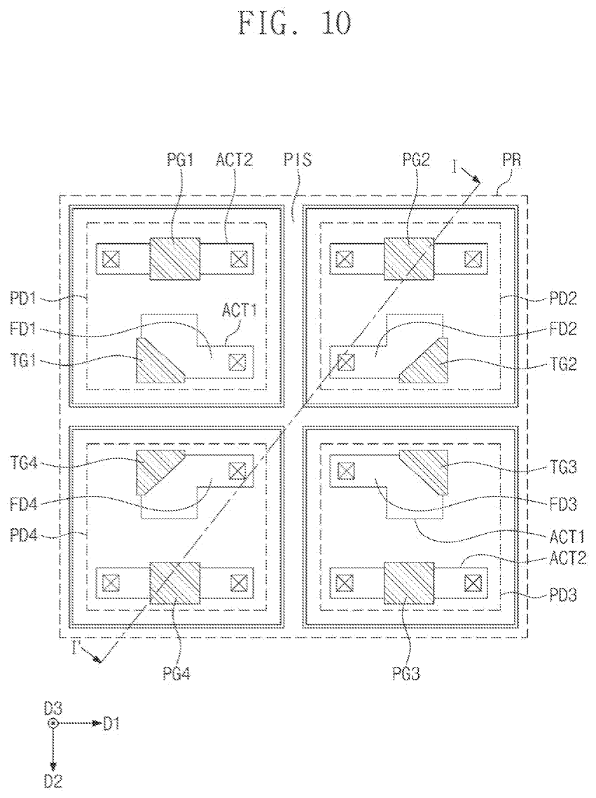

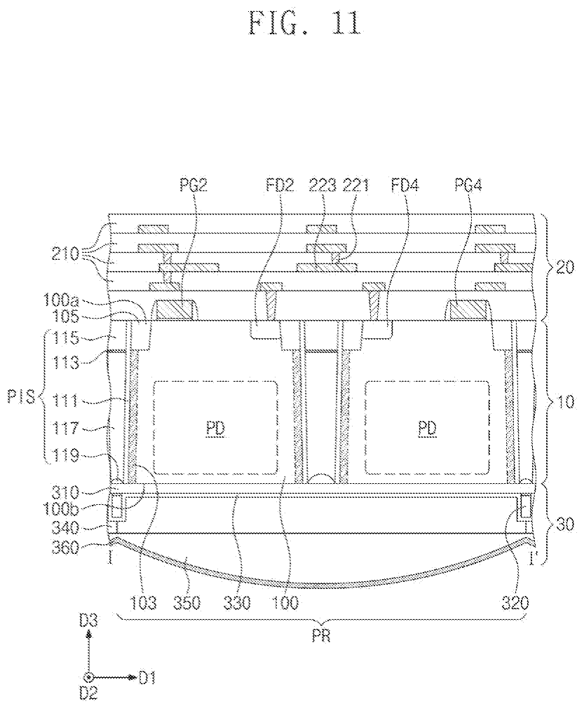

FIG. 10 is a plan view illustrating an image sensor according to an embodiment of the disclosure. FIG. 11 is a sectional view taken along a line I-I′ of FIG. 10 to illustrate an image sensor according to an embodiment of the disclosure.

In FIGS. 10 and 11, first to fourth photoelectric conversion regions PD1, PD2, PD3, and PD4 may be provided in the pixel region PR of the semiconductor substrate 100. The first to fourth photoelectric conversion regions PD1, PD2, PD3, and PD4 may be configured to convert light, which is incident from the outside, to electrical signals. That is, four photoelectric conversion regions PD1, PD2, PD3, and PD4 may be provided in each pixel region PR.

The first to fourth photoelectric conversion regions PD1, PD2, PD3, and PD4 may be impurity regions, which are doped with impurities of a conductivity type (i.e., the second conductivity type) different from the first conductivity type of the semiconductor substrate 100. The semiconductor substrate 100 of the first conductivity type and the first to fourth photoelectric conversion regions PD1, PD2, PD3, and PD4 may constitute photodiodes. That is, the semiconductor substrate 100 of the first conductivity type and each of the first to fourth photoelectric conversion regions PD1, PD2, PD3, and PD4 may form a junction serving as a photodiode. In the case where light is incident into the first to fourth photoelectric conversion regions PD1, PD2, PD3, and PD4 constituting the photodiode, photocharges may be generated and accumulated in proportion to an intensity of the incident light.

Each pixel region PR may be configured to measure a distance to a target object from a difference in phase between the electrical signals, which are output from the first to fourth photoelectric conversion regions PD1, PD2, PD3, and PD4, to examine whether the target object is in focus or the degree to which it is out of focus, and to automatically correct the focus of the image sensor based the examined result. That is, the image sensor may be configured to execute an auto-focusing function.

The pixel isolation structure PIS defining the pixel region PR may be provided in the semiconductor substrate 100. The pixel isolation structure PIS may include the liner insulating pattern 111, the etch stop layer 113, the gapfill insulating pattern 115, the air gap 117, and the capping pattern 119. In one embodiment, the pixel isolation structure PIS may further include the inner liner insulating pattern 112 and the sacrificial pattern 116. That is, the pixel isolation structure PIS may be provided to have substantially the same features as that of FIGS. 5A to 5C.

When viewed in a plan view, the pixel isolation structure PIS may be provided to enclose or cross the pixel region PR. In one embodiment, the pixel isolation structure PIS may include portions, which are extended in a first direction D1 to be parallel to each other, and portions, which are extended in a second direction D2 to be parallel to each other. In one embodiment, the pixel isolation structure PIS may include portions passing through the center of the pixel region PR in the first and second directions D1 and D2. Thus, the first to fourth photoelectric conversion regions PD1, PD2, PD3, and PD4 may be spaced apart from each other, with the pixel isolation structure PIS interposed therebetween, in the first and second directions D1 and D2.

Since the pixel isolation structure PIS includes the air gap 117 having a lower refractive index than the liner insulating pattern 111, the pixel isolation structure PIS may physically reflect the incident light, between the first to fourth photoelectric conversion regions PD1, PD2, PD3, and PD4. That is, it may be possible to prevent the incident light from being absorbed by the pixel isolation structure PIS between the first to fourth photoelectric conversion regions PD1, PD2, PD3, and PD4 and thereby to increase the quantum efficiency of the image sensor.

The lattice structure 320 may be disposed on the planarization insulating layer 310 of the optically-transparent layer 30. The lattice structure 320 may have a lattice shape that is similar to the pixel isolation structure PIS. When viewed in a plan view, the lattice structure 320 may be overlapped with the pixel isolation structure PIS. However, the lattice structure 320 may not be disposed between the first to fourth photoelectric conversion regions PD1, PD2, PD3, and PD4.

The color filters 340 may be disposed on the protection layer 330. Each of the color filters 340 may be formed to correspond to the pixel region PR. The color filters 340 may be provided to fill empty regions defined by the lattice structure 320. That is, each of the color filters 340 may be provided to correspond to the first to fourth photoelectric conversion regions PD1, PD2, PD3, and PD4 of a corresponding one of the pixel regions PR.

The micro lenses 350 may be located on the color filters 340. The micro lenses 350 may be disposed on the color filters 340 to correspond to the pixel regions PR, respectively. In one embodiment, the micro lenses 350 may be disposed in common on the first to fourth photoelectric conversion regions PD1, PD2, PD3, and PD4.

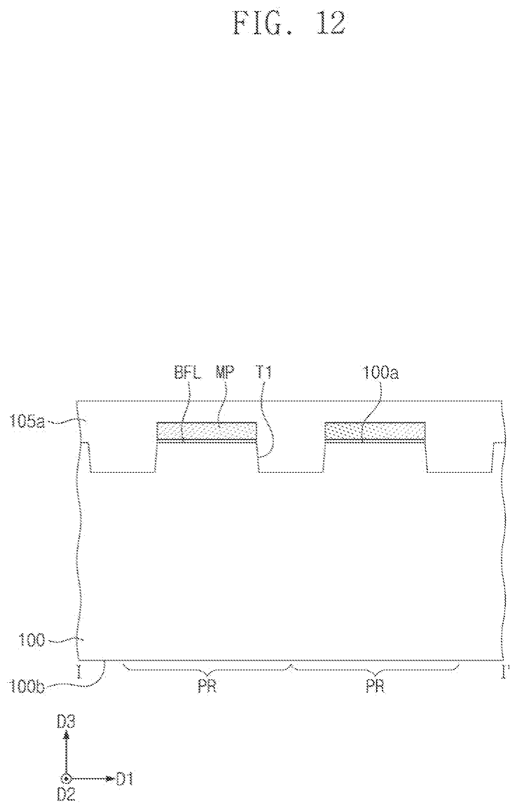

FIGS. 12 to 19 are sectional views taken along the line I-I′ of FIG. 3 to illustrate a method of fabricating an image sensor according to an embodiment of the disclosure.

In FIG. 12, the semiconductor substrate 100 of the first conductivity type (e.g., p-type) may be provided. The semiconductor substrate 100 may have the first surface 100a and the second surface 100b, which are opposite to each other. The semiconductor substrate 100 may include a bulk silicon substrate of a first conductivity type and an epitaxial layer, which is formed on the bulk silicon substrate and is of the first conductivity type. Here, the epitaxial layer may be formed by a selective epitaxial growth (SEG) process using the bulk silicon substrate as a seed, and the epitaxial layer may be doped with impurities of the first conductivity type, during the epitaxial growth process.

In an embodiment, the semiconductor substrate 100 may be a bulk semiconductor substrate including a well of the first conductivity type, a silicon-on-insulator (SOI) substrate, a germanium substrate, a germanium-on-insulator (GOI) substrate, or a silicon-germanium substrate.

The device isolation trench T1 may be formed by patterning the first surface 100a of the semiconductor substrate 100. The device isolation trench T1 may define the first and second active portions ACT1 and ACT2 of FIG. 3. The formation of the device isolation trench T1 may include forming a buffer layer BFL and a mask pattern MP on the first surface 100a of the semiconductor substrate 100 and anisotropically etching the semiconductor substrate 100 using the mask pattern MP as an etch mask.

The buffer layer BFL may be formed by performing a deposition process or a thermal oxidation process on the first surface 100a of the semiconductor substrate 100. The buffer layer BFL may include a silicon oxide layer. The mask pattern MP may be formed of or include at least one of silicon nitride or silicon oxynitride.

Thereafter, a device isolation insulating layer 105a may be formed to fill the device isolation trench T1. The device isolation insulating layer 105a may be formed by thickly depositing an insulating material on the semiconductor substrate 100 with the device isolation trench T1. The device isolation insulating layer 105a may fill the device isolation trench T1 and may cover the mask pattern MP.

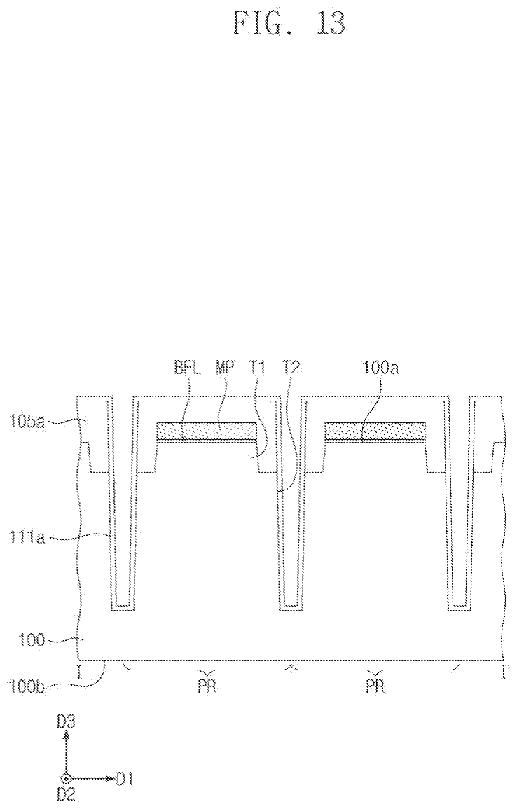

In FIG. 13, the pixel isolation trench T2 and a liner insulating layer 111a may be formed to define the pixel regions PR in the semiconductor substrate 100.

The pixel isolation trench T2 may be formed by patterning the device isolation insulating layer 105a and the first surface 100a of the semiconductor substrate 100. In one embodiment, the formation of the pixel isolation trench T2 may include forming a second mask pattern on the device isolation insulating layer 105a and removing a portion of the semiconductor substrate 100 using the second mask pattern as an etch mask.

The pixel isolation trench T2 may be vertically extended from the first surface 100a of the semiconductor substrate 100 toward the second surface 100b to expose a portion of a side surface of the semiconductor substrate 100. The pixel isolation trench T2 may be formed to be deeper than the device isolation trench T1 and may penetrate a portion of the device isolation trench T1. The pixel isolation trench T2 may be a deep trench which has an aspect ratio of about 10:1 to 15:1.

A width of the pixel isolation trench T2 may gradually decrease as a distance from the first surface 100a of the semiconductor substrate 100 increases in a direction toward the second surface 100b. That is, the pixel isolation trench T2 may have an inclined side surface. In one embodiment, the width of the pixel isolation trench T2 may be constant. In this case, the pixel isolation trench T2 may have a side surface parallel to the third direction D3. A bottom surface of the pixel isolation trench T2 may be spaced apart from the second surface 100b of the semiconductor substrate 100.

Thereafter, the liner insulating layer 111a may be formed to cover an inner surface of the pixel isolation trench T2. The liner insulating layer 111a may be formed to uniformly cover the inner surface of the pixel isolation trench T2 and a top surface of the device isolation insulating layer 105a. The liner insulating layer 111a may be deposited by a deposition method having a good step-coverage property. In one embodiment, the liner insulating layer 111a may be formed of or include at least one of silicon oxide, silicon nitride, and/or silicon oxynitride. The liner insulating layer 111a may be deposited to a thickness of about 30 Å to 350 Å.

In an embodiment, the liner insulating layer 111a may include first to third liner insulating layers. That is, the liner insulating layer 111a may be provided to include a plurality of layers. The first to third liner insulating layers may be sequentially formed in the pixel isolation trench T2. The second liner insulating layer may be located between the first and third liner insulating layer. The first to third liner insulating layers may be formed of or include different materials or the same material. In one embodiment, the first and third liner insulating layers may be formed of or include silicon oxide. The second liner insulating layer may be formed of or include silicon nitride.

Next, a doping process may be performed on the liner insulating layer 111a. The doping process may include doping the liner insulating layer 111a with impurities of the first conductivity type. In an embodiment, the doping process may include a beam line ion implantation process, a gas phase doping process, and a plasma doping (PLAD) process. In the plasma doping process, a gaseous source material may be supplied into a process chamber. The source material may be ionized by plasma, and then, the ionized source materials may be injected into the liner insulating layer 111a by applying a bias of high voltage to an electrostatic chuck, on which the semiconductor substrate 100 is loaded. In this case, the liner insulating layer 111a may have a uniform impurity concentration, regardless of vertical position or height.

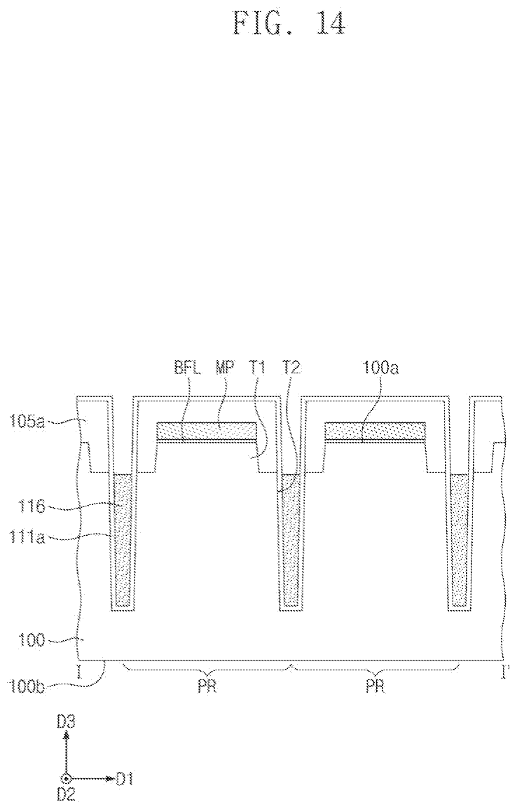

In FIG. 14, the sacrificial pattern 116 may be formed to fill a lower portion of the pixel isolation trench T2.

In one embodiment, a sacrificial layer may be formed on the device isolation insulating layer 105a to fill the pixel isolation trench T2. Here, the sacrificial layer may cover the liner insulating layer 111a. The sacrificial layer may be formed using a layer-forming technology, such as chemical vapor deposition (CVD) or atomic layer deposition (ALD) technologies, which have good step coverage properties. In one embodiment, the sacrificial layer may be formed of or include at least one of undoped polysilicon, silicon-germanium (SiGe), silicon oxide, silicon nitride, and/or silicon oxynitride.

Thereafter, the sacrificial pattern 116 may be formed by removing a portion of the sacrificial layer from an upper portion of the pixel isolation trench T2 and the top surface of the device isolation insulating layer 105a. The top surface of the sacrificial pattern 116 may be located at the same level as a bottom surface of the device isolation trench T1. That is, the sacrificial pattern 116 may be formed to fill a lower region of the pixel isolation trench T2.

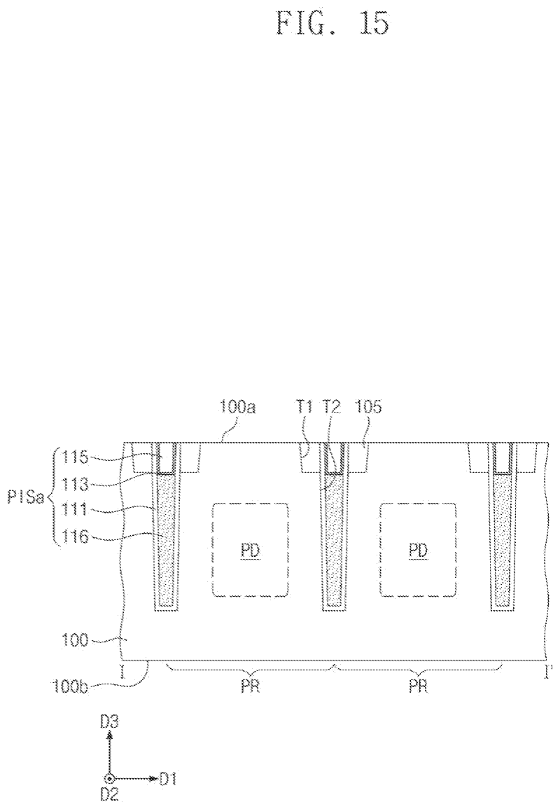

In FIG. 15, a preliminary pixel isolation structure PISa including the liner insulating pattern 111, the etch stop layer 113, the gapfill insulating pattern 115, and the sacrificial pattern 116 may be formed in the pixel isolation trench T2.

In one embodiment, a preliminary etch stop layer may be formed to conformally cover the top surface of the sacrificial pattern 116 and the side and top surfaces of the liner insulating layer 111a. The preliminary etch stop layer may have a uniform thickness. In one embodiment, the preliminary etch stop layer may be formed using a layer-forming technology, such as chemical vapor deposition (CVD) or atomic layer deposition (ALD) technologies, which have good step coverage properties. In an embodiment, the preliminary etch stop layer may be formed of or include at least one of metal oxide materials, metal oxynitride materials, metal silicon oxide materials, and/or metal silicon oxynitride materials.

In an embodiment, the preliminary etch stop layer may be formed on only the bottom surface of the gapfill insulating pattern 115, as shown in FIG. 5A. In one embodiment, the formation of the preliminary etch stop layer may be omitted.

Next, an insulating gapfill layer may be formed on the sacrificial pattern 116 and the etch stop layer 113 to fill an upper portion of the pixel isolation trench T2. On the first surface 100a of the semiconductor substrate 100, the insulating gapfill layer may cover the liner insulating layer 111a. The insulating gapfill layer may be formed using a layer-forming technology, such as chemical vapor deposition (CVD) or atomic layer deposition (ALD) technologies, which have good step coverage properties. In an embodiment, the insulating gapfill layer may be formed of or include at least one of silicon oxide, silicon nitride, and/or silicon oxynitride.

Thereafter, a planarization process may be performed to remove the mask pattern MP and expose the first surface 100a of the semiconductor substrate 100. Accordingly, the device isolation insulating layer 105a, the liner insulating layer 111a, the preliminary etch stop layer, and the insulating gapfill layer may be partially removed. As a result, the device isolation layer 105 may be formed from the device isolation insulating layer 105a. The liner insulating pattern 111 may be formed from the liner insulating layer 111a. The etch stop layer 113 may be formed from the preliminary etch stop layer. The gapfill insulating pattern 115 may be formed from the insulating gapfill layer.

Thus, the preliminary pixel isolation structure PISa including the liner insulating pattern 111, the etch stop layer 113, the gapfill insulating pattern 115, and the sacrificial pattern 116 may be formed in the pixel isolation trench T2. A top surface of the preliminary pixel isolation structure PISa and a top surface of the device isolation layer 105 may be located at the same level.

Next, the photoelectric conversion regions PD of the second conductivity type may be formed in the semiconductor substrate 100. The photoelectric conversion regions PD may be formed by injecting impurities, which have a conductivity type (e.g., the second conductivity type or n-type) different from the first conductivity type, into the semiconductor substrate 100. The photoelectric conversion regions PD may be spaced apart from the first surface 100a and the second surface 100b of the semiconductor substrate 100. In one embodiment, the photoelectric conversion regions PD may be formed before the formation of the preliminary pixel isolation structure PISa.

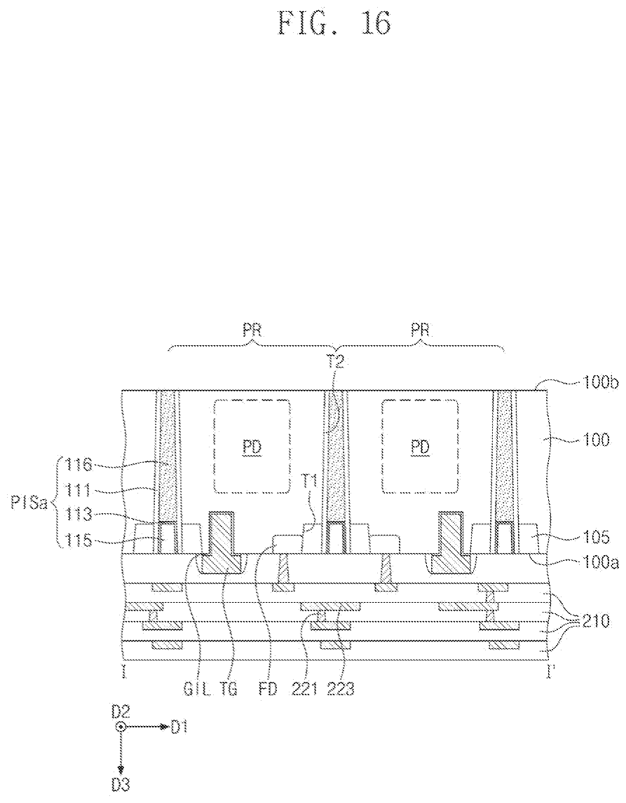

In FIG. 16, the MOS transistors constituting the pixel circuits may be formed on the first surface 100a of the semiconductor substrate 100, the semiconductor substrate 100 may be inverted, and then, a thinning process may be performed on the inverted semiconductor substrate 100.

In one embodiment, transfer gate electrodes TG may be formed in the pixel regions PR, respectively. The formation of the transfer gate electrodes TG may include patterning the semiconductor substrate 100 to form a gate recess region in each of the pixel regions PR, forming a gate insulating layer to conformally cover an inner surface of the gate recess region, forming a gate conductive layer to fill the gate recess region, and patterning the gate conductive layer. The pixel gate electrodes of the pixel transistors may be formed in the pixel regions PR, respectively, when the transfer gate electrodes TG are formed by patterning the gate conductive layer.

The floating diffusion regions FD may be formed in portions of the semiconductor substrate 100, each of which is located at a side of the transfer gate electrode TG, after the formation of the transfer gate electrodes TG. The floating diffusion regions FD may be formed by injecting impurities of the second conductivity type into the semiconductor substrate 100. The source/drain regions of the pixel transistors may be formed when the floating diffusion regions FD are formed.

An interconnection structure including the interlayer insulating layers 210, the contact plugs 221, and the metal lines 223 may be formed on the first surface 100a of the semiconductor substrate 100. The interlayer insulating layers 210 may cover the MOS transistors constituting the pixel circuits. The interlayer insulating layers 210 may be formed of a material having a good gap-filling property and may be formed to have a substantially flat top surface. The contact plugs 221, which are connected to the floating diffusion region FD or the pixel transistors, may be formed in the interlayer insulating layers 210. The metal lines 223 may be formed between the interlayer insulating layers 210. In an embodiment, the contact plugs 221 and the metal lines 223 may be formed of or include at least one of copper (Cu), aluminum (Al), tungsten (W), titanium (Ti), molybdenum (Mo), tantalum (Ta), titanium nitride (TiN), tantalum nitride (TaN), zirconium nitride (ZrN), tungsten nitride (WN), or alloys thereof.

Next, a thinning process may be performed to remove a portion of the semiconductor substrate 100 or to reduce a vertical thickness of the semiconductor substrate 100. The thinning process may include grinding or polishing the second surface 100b of the semiconductor substrate 100 and performing an anisotropic and/or isotropic etching process. The semiconductor substrate 100 may be inverted for the thinning process.

In an embodiment, the grinding or polishing process may be performed to remove the bulk silicon substrate of the semiconductor substrate 100 and expose the epitaxial layer. The anisotropic or isotropic etching process may be performed to remove surface defects, which may exist on the exposed surface of the epitaxial layer. The exposed surface of the epitaxial layer may correspond to the second surface 100b of the semiconductor substrate 100.

As a result of the thinning process on the semiconductor substrate 100, the sacrificial pattern 116 of the preliminary pixel isolation structure PISa may be exposed to the outside at the second surface 100b of the semiconductor substrate 100. That is, the bottom surface of the preliminary pixel isolation structure PISa and the second surface 100b of the semiconductor substrate 100 may be located at the same level.

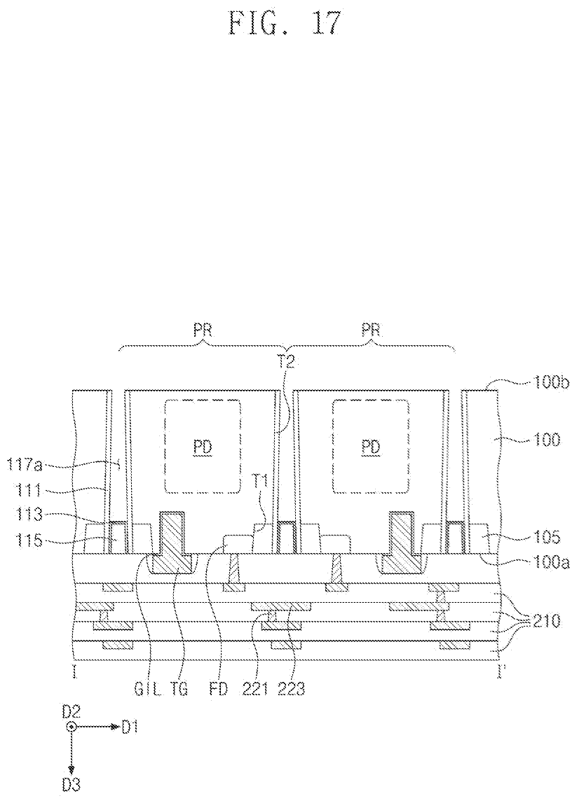

In FIG. 17, the preliminary pixel isolation structure may be partially removed to form an internal space.

In one embodiment, the sacrificial pattern 116 of the preliminary pixel isolation structure PISa may be removed. An etching process may be performed on the sacrificial pattern 116, which is exposed to the outside by the thinning process. The etching process may include a dry etching process and a wet etching process. The etching process may be performed using an etch recipe that has an etch selectivity with respect to the etch stop layer 113 and the sacrificial pattern 116. That is, the etching process may be performed to selectively remove only the sacrificial pattern 116.

The etching process may be performed to expose the etch stop layer 113 between the sacrificial pattern 116 and the gapfill insulating pattern 115. The etch stop layer 113 may be formed of or include a material, which exhibits a low etch rate or an etch resistant property in an etching process of removing polysilicon. Accordingly, an internal space 117a may be formed in the pixel isolation trench T2. The internal space 117a may be connected to the outside through the second surface 100b of the semiconductor substrate 100.

In an embodiment, the liner insulating pattern 111 of the preliminary pixel isolation structure PISa may include first to third liner insulating patterns. In this case, the internal space 117a may be formed by removing only at least one of the first to third liner insulating patterns through an etching process. In one embodiment, only the second line insulating pattern between the first and third liner insulating patterns may be removed to form the internal space 117a between the first and third liner insulating patterns. In this case, the pixel isolation structure PIS including the liner insulating pattern 111, the inner liner insulating pattern 112, and the sacrificial pattern 116 may be formed, as shown in the embodiment of FIG. 5C.

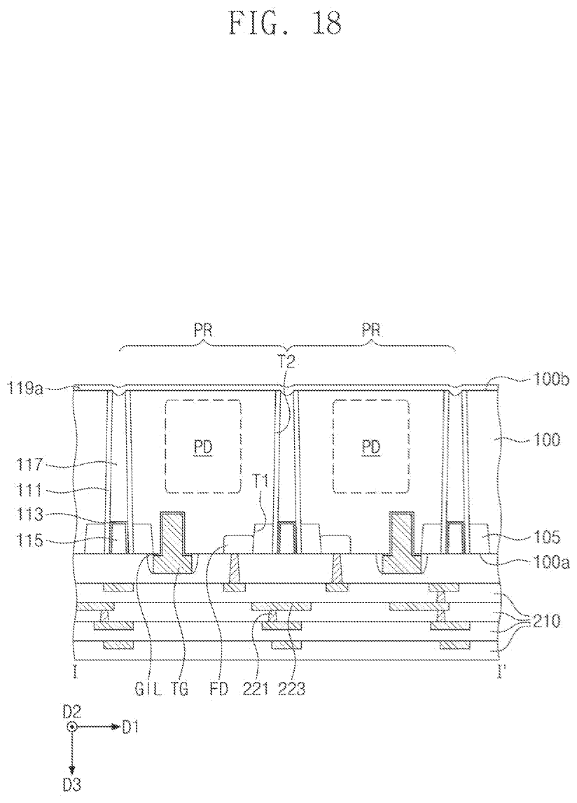

In FIG. 18, a capping layer 119a may be formed on the second surface 100b of the semiconductor substrate 100 to form the air gap 117 in the pixel isolation trench T2.

In one embodiment, the capping layer 119a may be formed using a deposition process having a poor step coverage property. In one embodiment, the capping layer 119a may be formed using a chemical vapor deposition (CVD) process or a physical vapor deposition (PVD) process. Due to an internal space in the pixel isolation trench T2, a portion of the capping layer 119a may be formed in the pixel isolation trench T2. The portion of the capping layer 119a in the pixel isolation trench T2 may have a convex shape that is curved toward the first surface 100a of the semiconductor substrate 100, and thus, the capping layer 119a may have a non-flat surface or an uneven structure.

In other words, since the pixel isolation trench T2 has a high aspect ratio and is formed by a deposition process having a poor step coverage property, the capping layer 119a may not be uniformly formed in the pixel isolation trench T2. In this case, the capping layer 119a may easily prevent the internal space 117a from being connected to the outside. Thus, the air gap 117 may be formed in the pixel isolation trench T2. The air gap 117 may be formed in the internal space 117a, from which the sacrificial pattern 116 is removed. Thus, the formation of the capping layer 119a may include an operation of forming the air gap 117 by sealing the internal space 117a form being exposed to the outside.

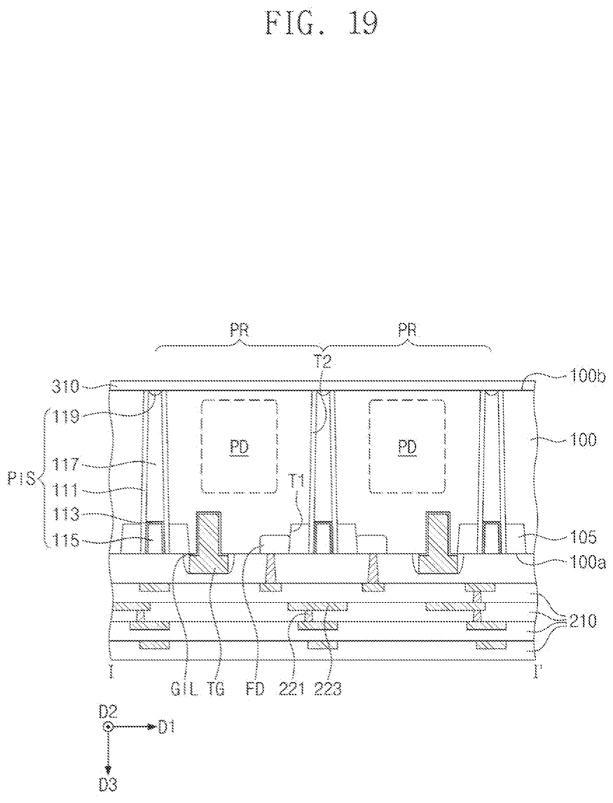

In FIG. 19, the planarization insulating layer 310 may be formed on the pixel isolation structure PIS in the semiconductor substrate 100 and the second surface 100b of the semiconductor substrate 100.

In one embodiment, a planarization process may be performed on the capping layer 119a. The planarization process may be performed to remove the capping layer 119a from the second surface 100b of the semiconductor substrate 100 and expose the second surface 100b of the semiconductor substrate 100. A portion of the capping layer 119a may be left in the pixel isolation trench T2, thereby serving as the capping pattern 119. As a result, the pixel isolation structure PIS including the liner insulating pattern 111, the etch stop layer 113, the gapfill insulating pattern 115, the air gap 117, and the capping pattern 119 may be formed.

Next, the planarization insulating layer 310 may be formed on the second surface 100b of the semiconductor substrate 100. The planarization insulating layer 310 may cover the surface of the capping pattern 119 and the second surface 100b of the semiconductor substrate 100. The planarization insulating layer 310 may be formed by depositing a metal oxide layer (e.g., an aluminum oxide layer and/or a hafnium oxide layer).

In an embodiment, during the planarization process, the capping layer 119a may be incompletely removed from the second surface 100b of the semiconductor substrate 100. The capping layer 119a may be left to have a uniform thickness on the second surface 100b of the semiconductor substrate 100. In one embodiment, the capping layer 119a may be substantially the same as a combination of the capping pattern 119 and the planarization insulating layer 310. The capping pattern 119 and the planarization insulating layer 310 may form a single object, as shown in FIG. 5B.

Referring back to FIG. 4, the lattice structure 320, the protection layer 330, the color filters 340, the micro lenses 350, and the passivation layer 360 may be sequentially formed on the planarization insulating layer 310.

The lattice structure 320 may include a light-blocking pattern and/or a low-refractive pattern. The light-blocking pattern may be formed of or include at least one of metallic materials (e.g., titanium, tantalum, or tungsten). The low-refractive pattern may be formed of or include a material whose refractive index is lower than the light-blocking pattern. The low-refractive pattern may be formed of an organic material and may have a refractive index of about 1.1 to 1.3. In one embodiment, the lattice structure 320 may be a polymer layer including silica nano-particles.

The protection layer 330 may be formed on the planarization insulating layer 310 to cover the surface of the lattice structure 320 with a substantially uniform thickness. The protection layer 330 may be a single- or multi-layered structure including at least one of an aluminum oxide layer and a silicon carbon oxide layer.

The color filters 340 may be formed on the protection layer 330 to correspond to the pixel regions PR, respectively. In one embodiment, the color filters 340 may include blue, red, and green color filters.

The micro lenses 350 may be formed on the color filters 340, respectively. The micro lenses 350 may have a convex shape and may have a specific curvature radius. The micro lenses 350 may be formed of or include an optically transparent resin.

The passivation layer 360 may conformally cover the top surfaces of the micro lenses 350. In an embodiment, the passivation layer 360 may be formed of or include an inorganic oxide material.

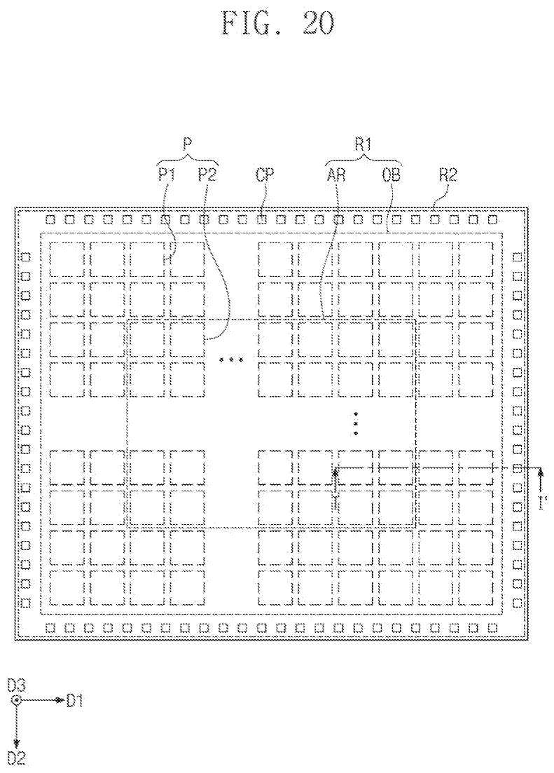

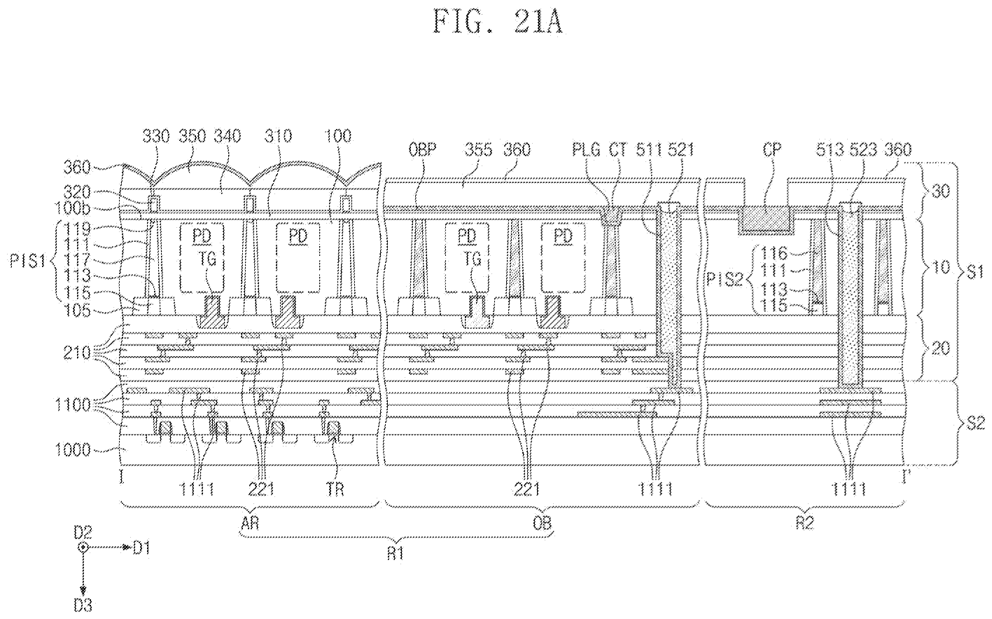

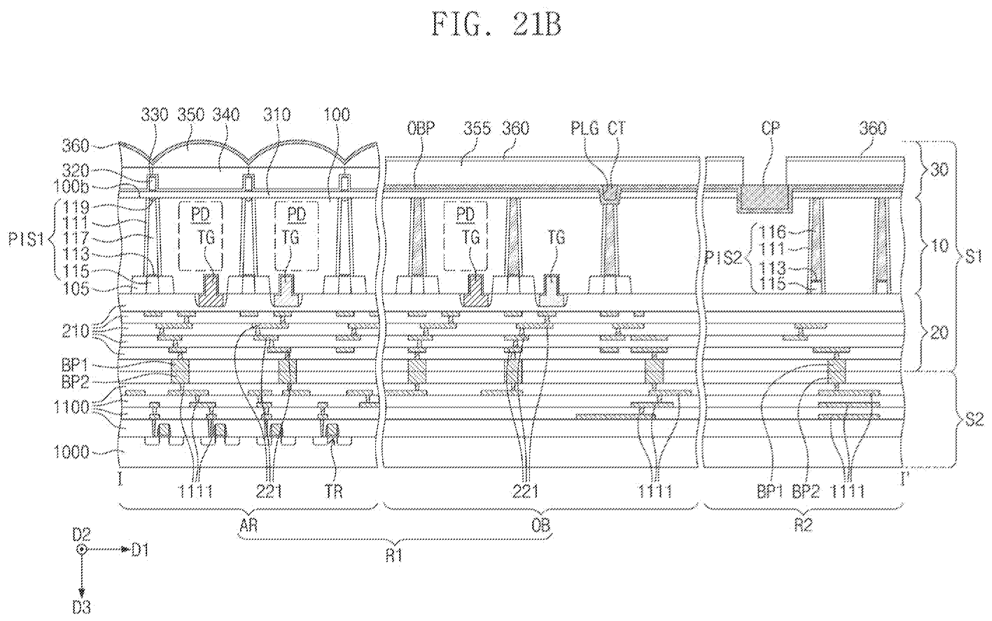

FIG. 20 is a schematic plan view illustrating an image sensor including a semiconductor device according to an embodiment of the disclosure. FIGS. 21A and 21B are sectional views taken along a line I-I′ of FIG. 20 to illustrate an image sensor according to an embodiment of the disclosure.

In FIGS. 20 and 21A, an image sensor may include a sensor chip S1 and a logic chip S2. The sensor chip S1 may include a pixel array region R1 and a pad region R2.

The pixel array region R1 may include a plurality of pixels P, which are two-dimensionally arranged in the first and second directions D1 and D2 crossing each other. Each of the pixels P may include a photoelectric conversion device and read-out devices. Each of the pixels P in the pixel array region R1 may be configured to output an electrical signal, which is produced by incident light.

The pixel array region R1 may include a light-receiving region AR and a light-blocking region OB. When viewed in a plan view, the light-blocking region OB may enclose the light-receiving region AR. In one embodiment, the light-blocking region OB may be provided to enclose the light-receiving region AR in four different directions (e.g., up, down, left, and rights directions), when viewed in a plan view. In an embodiment, reference pixels P1, to which light is not incident, may be provided in the light-blocking region OB, and in this case, by comparing a charge amount, which is obtained from the unit pixel P2 in the light-receiving region AR, with an amount of charges generated in the reference pixel P1, it may be possible to calculate a magnitude of an electrical signal generated by the unit pixel P2.

A plurality of conductive pads CP, which are used to input or output control signals and photoelectric signals, may be disposed in the pad region R2. When viewed in a plan view, the pad region R2 may enclose the pixel array region R1. Thus, the pad region R2 may be electrically coupled to external devices easily. The conductive pads CP may be used to transmit electrical signals, which are generated in the unit pixels P, to an external device.

In the light-receiving region AR, the sensor chip S1 may have the same technical features as the image sensor described above. That is, the sensor chip S1 may include the photoelectric conversion layer 10 between the pixel circuit layer 20 and the optically-transparent layer 30.

A pixel isolation structure may include a first pixel isolation structure PIS1 in the light-receiving region AR and a second pixel isolation structure PIS2 in the light-blocking region OB and the pad region R2. The first and second pixel isolation structures PIS1 and PIS2 may include the liner insulating pattern 111, the etch stop layer 113, and the gapfill insulating pattern 115. The first pixel isolation structure PIS1 may include the air gap 117 and the capping pattern 119. The second pixel isolation structure PIS2 may include the sacrificial pattern 116. That is, the sacrificial pattern 116 may be omitted from the first pixel isolation structure PIS1, and the air gap 117 may be omitted from the second pixel isolation structure PIS2.

In one embodiment, the first pixel isolation structure PIS1 may be the pixel isolation structure PIS, which is formed by the process of fabricating the image sensor of FIGS. 12 to 19 to include the air gap 117 but not the sacrificial pattern 116. The second pixel isolation structure PIS2 may be the preliminary pixel isolation structure PISa, which is formed by the process of fabricating the image sensor of FIGS. 12 to 19 to include the sacrificial pattern 116. In other words, since light is not incident into the light-blocking region OB and the pad region R2, it may be unnecessary to remove the sacrificial pattern 116 of the second pixel isolation structure PIS2. Thus, it may be possible to simplify the fabricating process and increase the endurance of the image sensor.

In one embodiment, the second pixel isolation structure PIS2 may include the air gap 117 and the capping pattern 119. That is, the sacrificial pattern 116 may be omitted from the second pixel isolation structure PIS2, and in this case, the second pixel isolation structure PIS2 may be substantially the same as the first pixel isolation structure PIS1.

In the light-blocking region OB, the optically-transparent layer 30 may include a light-blocking pattern OBP, a back-side contact plug PLG, a contact pattern CT, an organic layer 355, and the passivation layer 360. A portion of the pixel isolation structure PIS may be connected to the back-side contact plug PLG in the light-blocking region OB.

The back-side contact plug PLG may have a width that is larger than that of the second pixel isolation structure PIS2. The back-side contact plug PLG may be formed of or include at least one of metallic materials and/or metal nitride materials. In one embodiment, the back-side contact plug PLG may be formed of or include titanium and/or titanium nitride.

The contact pattern CT may be buried in a contact hole with the back-side contact plug PLG. The contact pattern CT may include a material different from the back-side contact plug PLG. In one embodiment, the contact pattern CT may be formed of or include aluminum (Al). The contact pattern CT may be electrically connected to the sacrificial pattern 116 of the second pixel isolation structure PIS2.

In the light-blocking region OB, the light-blocking pattern OBP may be continuously extended from the back-side contact plug PLG and may be disposed on a top surface of the planarization insulating layer 310. That is, the light-blocking pattern OBP may include the same material as the back-side contact plug PLG. The light-blocking pattern OBP may be formed of or include at least one of metallic materials and/or metal nitride materials. In one embodiment, the light-blocking pattern OBP may be formed of or include titanium and/or titanium nitride. The light-blocking pattern OBP may not be extended to the light-receiving region AR of the pixel array region R1.

The light-blocking pattern OBP may prevent light from being incident into the photoelectric conversion regions PD, which are provided in the light-blocking region OB. The photoelectric conversion regions PD in the reference pixels P1 of the light-blocking region OB may output a noise signal, not a photoelectric signal. The noise signal may be produced by electrons, which are generated by heat or a dark current.

In the light-blocking region OB, the organic layer 355 and the passivation layer 360 may be provided on the light-blocking pattern OBP. The organic layer 355 may be formed of or include the same material as the micro lenses 350.

In the light-blocking region OB, a first penetration conductive pattern 511 may be provided to penetrate the semiconductor substrate 100 and may be electrically connected to the metal lines 223 of the pixel circuit layer 20 and an interconnection structure 1111 of the logic chip S2. The first penetration conductive pattern 511 may have bottom surfaces located at different levels. A first gapfill pattern 521 may be provided within the first penetration conductive pattern 511. The first gapfill pattern 521 may be formed of or include a low-refractive material and may exhibit an insulating property.

In the pad region R2, the conductive pads CP may be provided on the second surface 100b of the semiconductor substrate 100. The conductive pads CP may be buried in the semiconductor substrate 100 and near the second surface 100b. In one embodiment, the conductive pads CP may be provided in pad trenches, which are formed in the second surface 100b of the semiconductor substrate 100 and are located in the pad region R2. The conductive pads CP may be formed of or include at least one of metallic materials (e.g., aluminum, copper, tungsten, titanium, tantalum, or alloys thereof). In a mounting process of an image sensor, bonding wires may be bonded to the conductive pads CP. The conductive pads CP may be electrically connected to an external device through a bonding wire.

In the pad region R2, a second penetration conductive pattern 513 may be provided to penetrate the semiconductor substrate 100 and may be electrically connected to the interconnection structure 1111 of the logic chip S2. The second penetration conductive pattern 513 may be extended to a region on the second surface 100b of the semiconductor substrate 100 and may be electrically connected to the conductive pad CP. A portion of the second penetration conductive pattern 513 may cover bottom and side surfaces of the conductive pads CP. A second gapfill pattern 523 may be provided in the second penetration conductive pattern 513. The second gapfill pattern 523 may be formed of or include a low-refractive material and may exhibit an insulating property. In the pad region R2, the second pixel isolation structures PIS2 may be provided around the second penetration conductive pattern 513.

The logic chip S2 may include a logic semiconductor substrate 1000, logic circuits TR, interconnection structures 1111 connected to the logic circuits TR, and logic interlayer insulating layers 1100. The uppermost one of the logic interlayer insulating layers 1100 may be bonded to the pixel circuit layer 20 of the sensor chip S1. The logic chip S2 may be electrically connected to the sensor chip S1 through the first and second penetration conductive patterns 511 and 513.

In FIGS. 20 and 21B, the first and second penetration conductive patterns 511 and 513 and the first and second gapfill patterns 521 and 523 of FIG. 21A may be omitted. Since bonding pads of the sensor and logic chips S1 and S2 are directly bonded to each other, the sensor and logic chips S1 and S2 may be electrically connected to each other.

In one embodiment, the sensor chip S1 of the image sensor may include first bonding pads BP1, which are placed in the uppermost portion of the pixel circuit layer 20. The logic chip S2 may include second bonding pads BP2, which are placed in the uppermost one of the logic interlayer insulating layers 1100. That is, the first bonding pads BP1 may be placed on a bottom surface of the sensor chip S1, and the second bonding pads BP2 may be placed on a top surface of the logic chip S2 and may be in contact with the first bonding pads BP1. The first and second bonding pads BP1 and BP2 may be formed of or include at least one of, for example, tungsten (W), aluminum (Al), copper (Cu), tungsten nitride (WN), tantalum nitride (TaN), or titanium nitride (TiN).

The first bonding pads BP1 of the sensor chip S1 and the second bonding pads BP2 of the logic chip S2 may be electrically connected to each other by a hybrid bonding method. The hybrid bonding method may mean a method of bonding two materials, which are of the same kind, at an interface therebetween (e.g., through a fusion process). In one embodiment, in the case where the first and second bonding pads BP1 and BP2 are formed of copper (Cu), they may be physically and electrically connected to each other in a Cu—Cu bonding manner.

According to an embodiment of the disclosure, an image sensor may include a pixel isolation structure, which is provided in a semiconductor substrate and includes a liner insulating pattern and an air gap. Here, a refractive index of the liner insulating pattern may be lower than a refractive index of the semiconductor substrate, and a refractive index of the air gap may be lower than the refractive index of the liner insulating pattern. Accordingly, it may be possible to prevent an incident light from being absorbed by the pixel isolation structure. Thus, the quantum efficiency (QE) of the image sensor may be increased, and this may make it possible to improve the electrical or optical characteristics of the image sensor.

While example embodiments of the disclosure have been particularly shown and described, it will be understood by one of ordinary skill in the art that variations in form and detail may be made therein without departing from the spirit and scope of the attached claims.

1. An image sensor comprising:
a semiconductor substrate of a first conductivity type, the semiconductor substrate comprising:
a first surface,
a second surface opposite to the first surface, and
a pixel region,
a photoelectric conversion region in the pixel region, the photoelectric conversion region having an impurity of a second conductivity type; and
a pixel isolation structure in the semiconductor substrate and configured to enclose the photoelectric conversion region,
wherein the pixel isolation structure comprises:
an air gap,
a liner insulating pattern between the air gap and the semiconductor substrate, and
a capping pattern adjacent to the second surface of the semiconductor substrate.

2. The image sensor of claim 1, wherein the pixel isolation structure further comprises:
a gapfill insulating pattern adjacent to the first surface of the semiconductor substrate; and
an etch stop layer on a bottom surface of the gapfill insulating pattern.

3. The image sensor of claim 2, wherein the etch stop layer extends between a side surface of the gapfill insulating pattern and the liner insulating pattern.

4. The image sensor of claim 1, wherein the capping pattern has a convex shape toward the first surface of the semiconductor substrate.

5. The image sensor of claim 1, wherein the liner insulating pattern comprises a horizontal portion and a vertical portion extended from the horizontal portion, and
wherein the horizontal portion is adjacent to the first surface of the semiconductor substrate.

6. The image sensor of claim 1, further comprising a planarization insulating layer on the second surface of the semiconductor substrate,
wherein the planarization insulating layer and the capping pattern include a same material, and
wherein the planarization insulating layer and the capping pattern do not have an observable interface in between.

7. The image sensor of claim 1, wherein the pixel isolation structure is extended from the first surface of the semiconductor substrate to the second surface of the semiconductor substrate.

8. The image sensor of claim 1, wherein a width of the pixel isolation structure decreases as a distance from the first surface of the semiconductor substrate increases in a direction toward the second surface of the semiconductor substrate.

9. The image sensor of claim 1, wherein a width of the pixel isolation structure increases as a distance from the first surface of the semiconductor substrate increases in a direction toward the second surface of the semiconductor substrate.

10. The image sensor of claim 1, wherein a width of the pixel isolation structure is largest at levels of the first surface and the second surface of the semiconductor substrate.

11. The image sensor of claim 1, wherein a first refractive index of the air gap is lower than a second refractive index of the liner insulating pattern.

12. The image sensor of claim 1, wherein the pixel isolation structure further comprises an inner liner insulating pattern and a sacrificial pattern, and
wherein the air gap is placed between the liner insulating pattern and the inner liner insulating pattern.

13. The image sensor of claim 12, wherein the capping pattern is placed between the liner insulating pattern and the inner liner insulating pattern.

14. An image sensor comprising:
a semiconductor substrate of a first conductivity type, the semiconductor substrate comprising:
a first surface,
a second surface opposite to the first surface, and
a pixel region,
a photoelectric conversion region in the pixel region, the photoelectric conversion region having an impurity of a second conductivity type;
a pixel isolation structure in the semiconductor substrate to define the pixel region; and
a device isolation layer adjacent to the first surface of the semiconductor substrate to define an active region,
wherein the pixel isolation structure comprises:
an air gap,
a liner insulating pattern between the air gap and the semiconductor substrate, and
a gapfill insulating pattern adjacent to the first surface of the semiconductor substrate, and
wherein the pixel isolation structure is provided to penetrate a portion of the device isolation layer and is extended from the first surface of the semiconductor substrate to the second surface of the semiconductor substrate.

15. The image sensor of claim 14, wherein the pixel isolation structure further comprises a capping pattern adjacent to the second surface of the semiconductor substrate, and
wherein the capping pattern has a convex shape toward the first surface of the semiconductor substrate.

16. The image sensor of claim 15, wherein the pixel isolation structure further comprises an etch stop layer between the gapfill insulating pattern and the capping pattern, and
wherein the etch stop layer is in contact with a bottom surface of the gapfill insulating pattern.

17. The image sensor of claim 16, wherein the air gap is placed between the gapfill insulating pattern and the capping pattern.

18. An image sensor comprising:
a semiconductor substrate comprising: a light-receiving region, a light-blocking region, a pad region, a first surface, a second surface opposite to the first surface;
a pixel isolation structure in the light-receiving region and the light-blocking region of the semiconductor substrate, the pixel isolation structure defining a plurality of pixel regions;
a transfer gate electrode on the first surface of the semiconductor substrate;
a plurality of photoelectric conversion regions in the light-receiving region and the light-blocking region of the semiconductor substrate;
a pixel circuit layer on the first surface of the semiconductor substrate; and
an optically-transparent layer on the second surface of the semiconductor substrate,
wherein the pixel isolation structure comprises a first pixel isolation structure on the light-receiving region and a second pixel isolation structure on the light-blocking region,
wherein the first pixel isolation structure comprises an air gap, and
wherein the second pixel isolation structure comprises a sacrificial pattern.

19. The image sensor of claim 18, wherein the sacrificial pattern is omitted from the first pixel isolation structure, and
wherein the air gap is omitted from the second pixel isolation structure.

20. The image sensor of claim 18, wherein, in the light-receiving region, the optically-transparent layer comprises micro lenses, and
wherein each of the micro lenses is disposed in common on the plurality of photoelectric conversion regions.

21. (canceled)

22. (canceled)

23. (canceled)

24. (canceled)

25. (canceled)
